(19) United States
(12) Patent Application Publication
(10) Pub. No.: US 2026/0190451 A1
(43) Pub. Date: Jul. 2, 2026

(54) INTEGRATED CIRCUIT DEVICE AND METHOD FOR FABRICATING THE SAME

(71) Applicant: TAIWAN SEMICONDUCTOR MANUFACTURING COMPANY, LTD., Hsinchu (TW)

(72) Inventors: Yi-Yi CHEN, Hsinchu City (TW); Chi-Yu LU, New Taipei City (TW); Chih-Liang CHEN, Hsinchu City (TW); Chen-Ling WU, Taoyuan City (TW); Ya-Chi CHOU, Hsinchu City (TW); Guo-Huei WU, Tainan City (TW)

(73) Assignee: TAIWAN SEMICONDUCTOR MANUFACTURING COMPANY, LTD., Hsinchu (TW)

(21) Appl. No.: 19/008,486

(22) Filed: Jan. 2, 2025

(51) Int. Cl. H10D 84/01; H10B 10/00; H10D 30/00; H10D 30/01; H10D 30/43; H10D 62/10; H10D 64/23; H10D 84/85

(52) U.S. Cl. CPC H10D 84/0186; H10B 10/125; H10D 30/014; H10D 30/019; H10D 30/43; H10D 30/501; H10D 62/121; H10D 64/251; H10D 84/0188; H10D 84/851

(57) ABSTRACT

An integrated circuit device includes first and second stack structures and a side connection structure. The first stack structure includes a first transistor and a second transistor stacked thereon. The second stack structure includes a third transistor and a fourth transistor stacked thereon. Each of the first to fourth transistors includes an active layer having a channel region and a source/drain region, a gate structure wrapping around the channel region, and a source/drain contact surrounding the source/drain region. The active layer and the side connection structure extend substantially along a first direction in a top view, and the gate structure extends substantially along a second direction orthogonal to the first direction in the top view. The side connection structure electrically connects one of the source/drain contact and the gate structure of the first transistor to one of the source/drain contact and the gate structure of the third transistor.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate,

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are respectively layout diagrams of upper and lower portions of an integrated circuit device in accordance with some embodiments of the present disclosure.

FIG. 1C is a perspective view of an integrated circuit device according to the layout diagrams in FIGS. 1A and 1B.

FIGS. 2-9C illustrate schematic cross-sectional views of intermediate stages in the manufacture of an integrated circuit device in accordance with some embodiments of the present disclosure.

FIGS. 10A and 10B are respectively layout diagrams of upper and lower portions of an integrated circuit device in accordance with some embodiments of the present disclosure.

FIG. 10C is a perspective view of an integrated circuit device according to the layout diagrams in FIGS. 10A and 10B.

FIGS. 11A and 11B are respectively layout diagrams of upper and lower portions of an integrated circuit device in accordance with some embodiments of the present disclosure.

FIG. 11C is a perspective view of an integrated circuit device according to the layout diagrams in FIGS. 11A and 11B.

FIGS. 12A and 12B are respectively layout diagrams of upper and lower portions of an integrated circuit device in accordance with some embodiments of the present disclosure.

FIG. 12C is a perspective view of an integrated circuit device according to the layout diagrams in FIGS. 12A and 12B.

FIGS. 13A and 13B are respectively layout diagrams of upper and lower portions of an integrated circuit device in accordance with some embodiments of the present disclosure.

FIG. 13C is a perspective view of an integrated circuit device according to the layout diagrams in FIGS. 13A and 13B.

FIGS. 14A and 14B are respectively layout diagrams of upper and lower portions of an integrated circuit device in accordance with some embodiments of the present disclosure.

FIG. 14C is a perspective view of an integrated circuit device according to the layout diagrams in FIGS. 14A and 14B.

FIGS. 15A and 15B are respectively layout diagrams of upper and lower portions of an integrated circuit device in accordance with some embodiments of the present disclosure.

FIG. 15C is a perspective view of an integrated circuit device according to the layout diagrams in FIGS. 15A and 15B.

FIGS. 16A and 16B are respectively layout diagrams of upper and lower portions of an integrated circuit device in accordance with some embodiments of the present disclosure.

FIG. 16C is a perspective view of an integrated circuit device according to the layout diagrams in FIGS. 16A and 16B.

FIGS. 17A and 17B are respectively layout diagrams of upper and lower portions of an integrated circuit device in accordance with some embodiments of the present disclosure.

FIG. 17C is a perspective view of an integrated circuit device according to the layout diagrams in FIGS. 17A and 17B.

FIGS. 18A and 18B are perspective views of upper and lower portions of an integrated circuit device in accordance with some embodiments of the present disclosure.

FIGS. 18C and 18D are perspective views of upper and lower portions of an integrated circuit device in accordance with some embodiments of the present disclosure.

FIGS. 19A and 19B are respectively layout diagrams of upper and lower portions of an integrated circuit device in accordance with some embodiments of the present disclosure.

FIGS. 19C and 19D are perspective views of an integrated circuit device according to the layout diagrams in FIGS. 19A and 19B.

FIGS. 20A-25C illustrate schematic cross-sectional views of intermediate stages in the manufacture of an integrated circuit device in accordance with some embodiments of the present disclosure.

FIGS. 26A and 26B are perspective views of an integrated circuit device in accordance with some embodiments of the present disclosure.

FIGS. 27A and 27B are respectively layout diagrams of upper and lower portions of an integrated circuit device in accordance with some embodiments of the present disclosure.

FIG. 27C is a perspective view of an integrated circuit device according to the layout diagrams in FIGS. 27A and 27B.

FIGS. 28A-37B illustrate schematic cross-sectional views of intermediate stages in the manufacture of an integrated circuit device in accordance with some embodiments of the present disclosure.

FIGS. 38A and 38B are respectively layout diagrams of upper and lower portions of an integrated circuit device in accordance with some embodiments of the present disclosure.

FIG. 38C is a perspective view of an integrated circuit device according to the layout diagrams in FIGS. 38A and 38B.

FIGS. 39A and 39B are respectively layout diagrams of upper and lower portions of an integrated circuit device in accordance with some embodiments of the present disclosure.

FIG. 39C is a perspective view of an integrated circuit device according to the layout diagrams in FIGS. 39A and 39B.

FIGS. 40A and 40B are respectively layout diagrams of upper and lower portions of an integrated circuit device in accordance with some embodiments of the present disclosure.

FIGS. 41A and 41B are respectively layout diagrams of upper and lower portions of an integrated circuit device in accordance with some embodiments of the present disclosure.

FIGS. 42A and 42B are respectively layout diagrams of upper and lower portions of an integrated circuit device in accordance with some embodiments of the present disclosure.

FIGS. 43A and 43B are respectively layout diagrams of upper and lower portions of an integrated circuit device in accordance with some embodiments of the present disclosure.

FIGS. 44A and 44B are respectively layout diagrams of upper and lower portions of an integrated circuit device including a full adder in accordance with some embodiments of the present disclosure.

FIG. 45A is a circuit diagram of a SRAM cell in accordance with some embodiments of the present disclosure.

FIGS. 45B and 45C are respectively layout diagrams of upper and lower portions of an integrated circuit device including the SRAM cell shown in FIG. 45A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

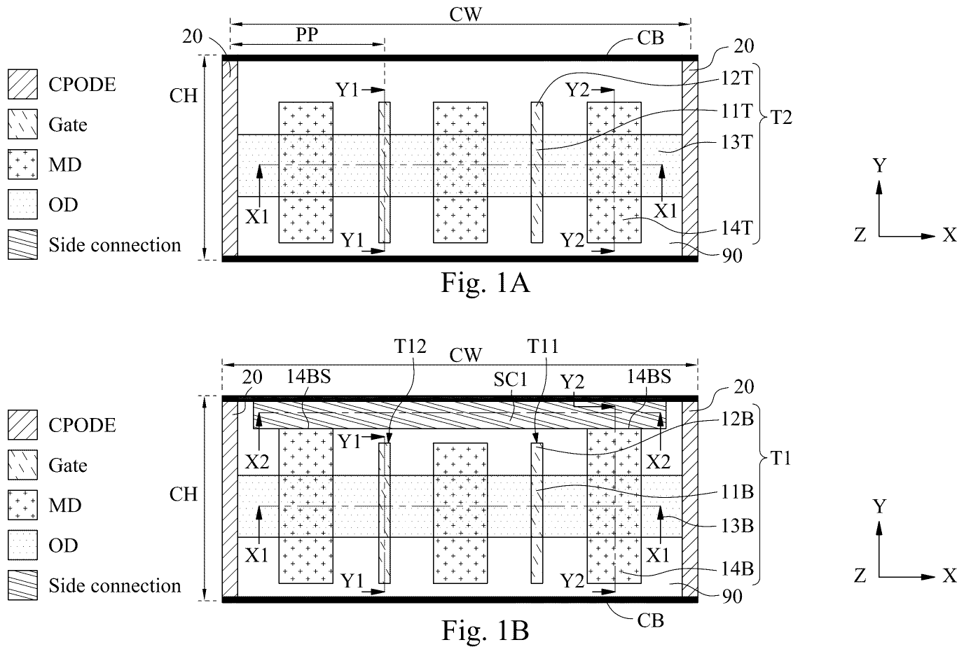

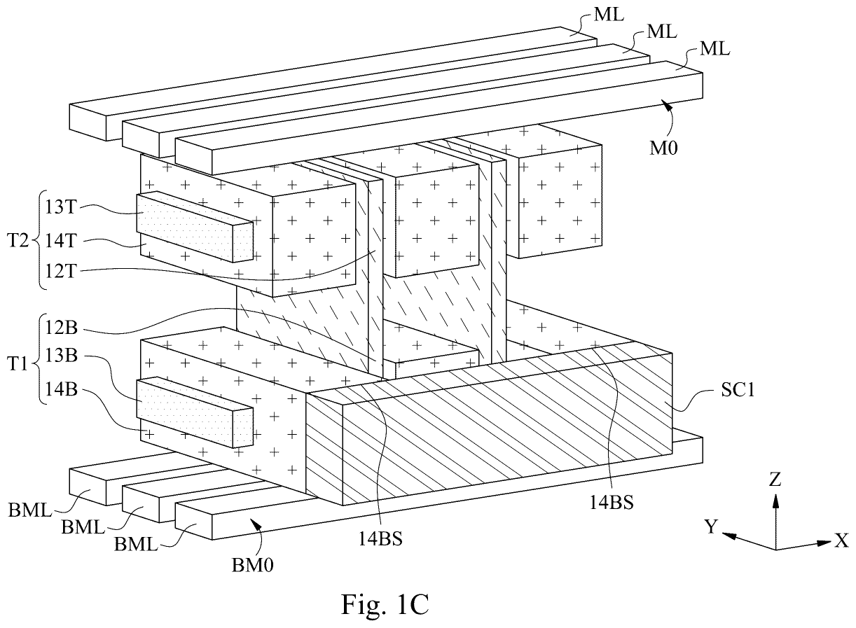

FIGS. 1A and 1B are respectively layout diagrams of upper and lower portions of an integrated circuit device in accordance with some embodiments of the present disclosure. The integrated circuit device is illustrated as a cell surrounded by a cell boundary indicated by bolded lines CB. The cell includes a cell height CH along the Y direction and a cell width CW along the X direction. In the present embodiments, the cell width CW spans over 3 gate pitches PP. In the layout diagrams of FIGS. 1A and 1B, active regions, also referred to as oxide-diffusion regions, denoted as “OD” in the context, extend substantially along the direction X. The active region may include one or more channel regions 11T/11B and one or more source/drain regions 13T/13B. In the context, the active regions (OD) may be respectively surrounded and spaced apart from each other by an isolation structure 90. Stated differently, in the layout diagrams, the region free of the active regions (OD) is where the isolation structure 90 is located. The isolation structure 90 may be a single-layer or a multi-layer structure. In some embodiments, the isolation structure 90 includes low-k dielectric materials, SiN, SiCN, SiOC, SiOCN or the like.

FIG. 1C is a perspective view of an integrated circuit device according to the layout diagrams in FIGS. 1A and 1B. Reference is made to FIGS. 1A-1C. The integrated circuit device may include one or plural complementary FET (CFET) structures, each of the CFET structures includes a bottom transistor T1 and a top transistor T2 vertically stacked over the bottom transistor T1.

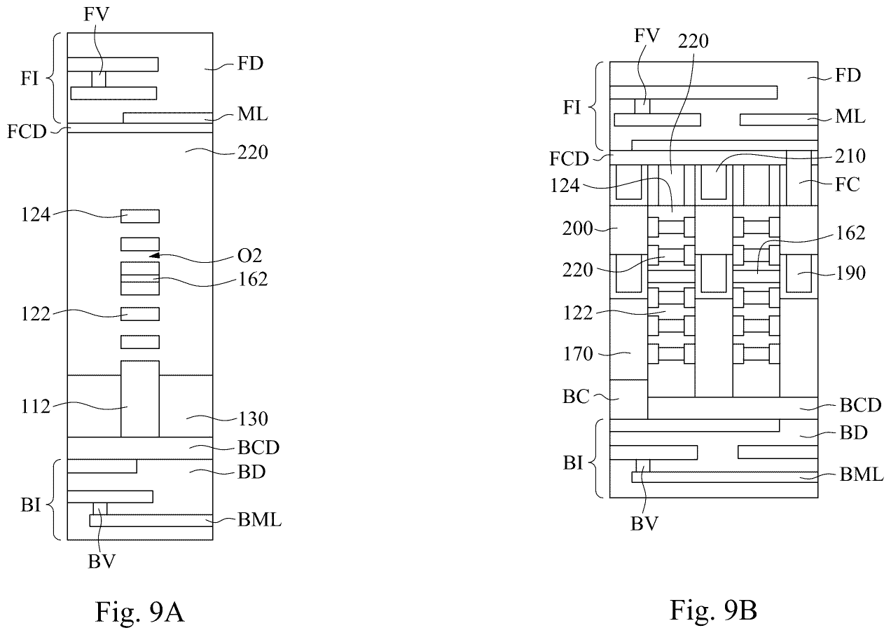

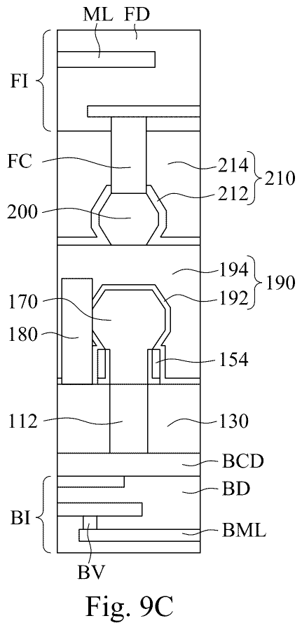

The bottom transistor T1 includes at least one bottom gate structure 12B, at least one bottom semiconductor channel region 11B within the active region OD and covered by the bottom gate structure 12B, bottom source/drain regions 13B, and bottom source/drain conductive structures 14B. The number of the bottom gate structures 12B may vary in a range from 1 to 10, depending on the desired number of channel regions for the bottom transistor T1. The bottom gate structure 12B wraps around the bottom semiconductor channel region 11B. The bottom source/drain regions 13B are on opposite sides of the at least one bottom semiconductor channel regions 11B. The bottom source/drain conductive structures 14B are formed on the bottom source/drain regions 13B, respectively. For example, the bottom source/drain conductive structure 14B may include a source/drain epitaxial structure (e.g., source/drain epitaxial structure as shown in FIG. 9B) and a source/drain metal contact (contact BC as shown in FIG. 9B) on the source/drain epitaxial structure.

The top transistor T2 includes at least one top semiconductor channel region 11T, a top gate structure 12T, top source/drain regions 13T, and top source/drain conductive structures 14T. The number of the top semiconductor channel regions 11T may vary in a range from 1 to 10, depending on the desired number of channel regions for the top transistor T2. The top gate structure 12T wraps around the at least one top semiconductor channel regions 11T. The top source/drain regions 13T are on opposite sides of the at least one top semiconductor channel regions 11T. The top source/drain conductive structures 14T are formed on the top source/drain regions 13T, respectively. For example, the top source/drain conductive structure 14T may include a source/drain epitaxial structure (e.g., source/drain epitaxial structure 200 as shown in FIG. 9C) and a source/drain metal contact (e.g., metal contact FC as shown in FIG. 9C) on the source/drain epitaxial structure.

In the present embodiments, the top gate structure 12T and the bottom gate structure 12B may share a continuous gate structure, such that the top gate structure 12T is electrically connected with the bottom gate structure 12B. In some other embodiments, in a CFET structure fabricated by a monolithic process, the top gate structure 12T can be electrically isolated from the bottom gate structure 12B by a middle dielectric layer (MDI) (not shown), in which the middle dielectric layer may separate the top gate structure 12T from the bottom gate structure 12B. In some embodiments, the bottom transistor T1 has a first conductivity type (e.g., n-type) and the top transistor T2 has a second conductivity type (e.g., p-type) different from the first conductivity type.

The channel regions 11T/11B can be formed by the nanostructures. The nanostructures may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures include silicon for N-type transistors. In other embodiments, the nanostructures include silicon germanium for P-type transistors. In some embodiments, the nanostructures may also be referred to as channels, channel layers, nanosheets, or nanowires for GAA transistors. The source/drain region(s) may be referred to a source or a drain, individually or collectively dependent upon the context. The source/drain regions can be source/drain epitaxy structures.

The gate structures 12T and 12B, denoted as “Gate”, extend in the direction Y. The gate structures can be polysilicon strips or high-k/metal gate structures. The high-k/metal gate structures may include a high-k dielectric layer surrounding the channel region(s) and a metal gate surrounding the high-k dielectric layer.

Source/drain conductive structures 14B and 14T, denoted as “MD”, are in contact with and electrically connect the source/drain regions 13B of the bottom transistor T1 and the source/drain regions 13T of the top transistor T2, respectively. The source/drain conductive structures 14B and 14T may include suitable metal and/or metal silicide.

A side connection structure SC1, denoted as “Side connection”, is in contact with a lateral side 14BS of one of the source/drain conductive structures 14B and a lateral side 14BS of another one of the source/drain conductive structures 14B, thereby establishing an electrical connection between the two source/drain conductive structures 14B of the bottom transistors T1. The side connection structure SC1 may extend substantially along the direction the same as that of the active regions, such as the direction X. And, the side connection structure SC1 may include a suitable conductive material, such as doped semiconductor, metal, and/or metal silicide. In the present embodiments, a top surface of the side connection structure SC1 is below a bottom surface of the channel region 11T of the top transistor T2.

In the layout diagrams, the cell may include two dielectric gates 20 at the two boundary lines oriented along the direction Y. The dielectric gates 20 and the gate structures 12T/12B extend along a same direction Y, and the dielectric gates 20 and the gate structures 12T/12B are spaced apart from each other by a same gate pitch PP along the direction X. The dielectric gate 20 is not a gate and does not function as a gate. Instead, the dielectric gate 20 is a dielectric feature that includes one or more dielectric materials (which can be called as “dielectric structure” in some embodiments) and functions as an isolation feature, in some instances. The dielectric gate 20 may be referred to as continuous polysilicon on oxide diffusion edge (CPODE), denoted as “CPODE.”

A frontside interconnect structure including plural metallization layers is formed on a frontside of the integrated circuit device. The number of metallization layers may vary according to design specifications of the integrated circuit. For example, a metallization layer M0 is formed on the frontside of the integrated circuit device. The metallization layers each comprise an inter-metal dielectric (IMD) layer, one or more horizontal interconnects, such as metal lines ML, respectively extending horizontally or laterally in the IMD layers, and vertical interconnects, such as conductive vias, respectively extending vertically in the IMD layers.

And, a backside interconnect structure including plural backside metallization layers is formed on a backside of the integrated circuit device. The number of backside metallization layers may vary according to design specifications of the integrated circuit. For example, a backside metallization layer BM0 is formed on the backside of the integrated circuit device. The backside metallization layers each comprise a backside inter-metal dielectric (IMD) layer, one or more horizontal interconnects, such as metal lines BML, respectively extending horizontally or laterally in the IMD layers, and vertical interconnects, such as conductive vias, respectively extending vertically in the backside IMD layers.

Through the configuration, the side connection structure SC1 electrically connects the source/drain conductive structure 14B of the transistor T11 to the source/drain conductive structure 14B of the transistor T12. The active layer of the transistor T11 is aligned with the active layer of the transistor T12 substantially along the direction X. And, the gate structure 12B of the transistors T11 and T12 are spaced apart from the side connection structure SC1.

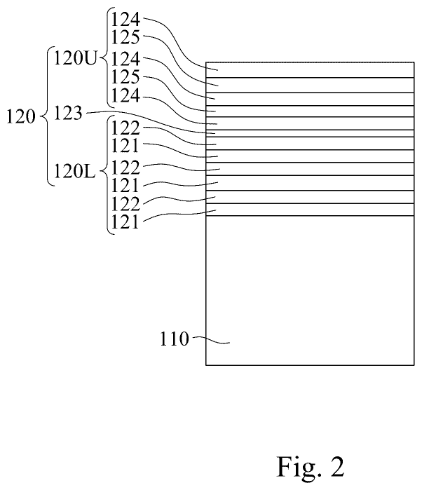

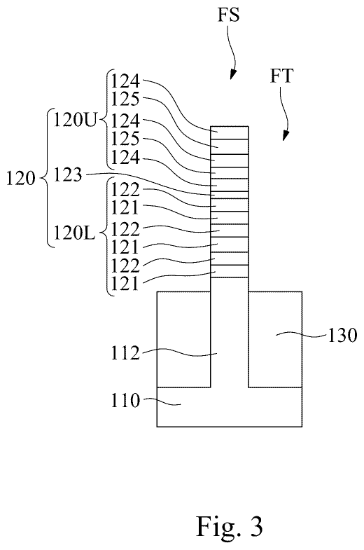

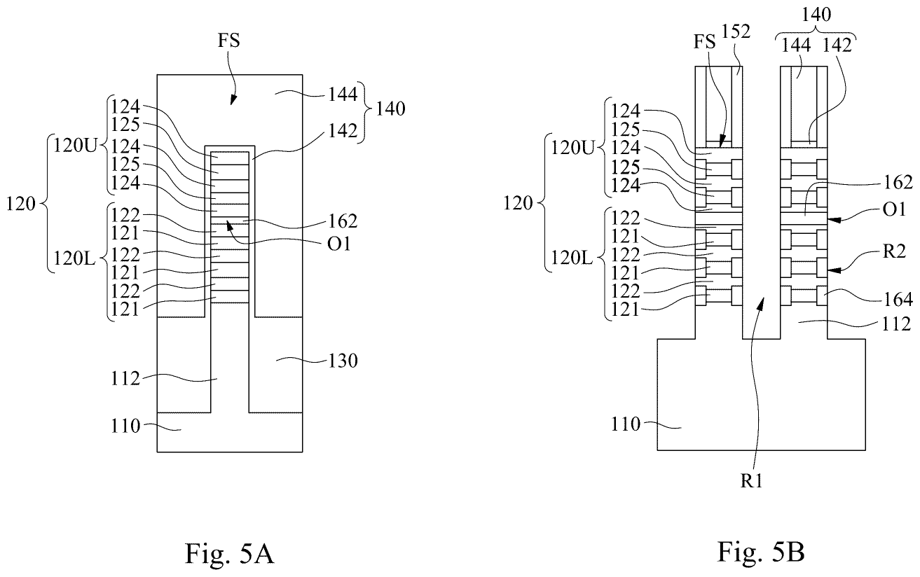

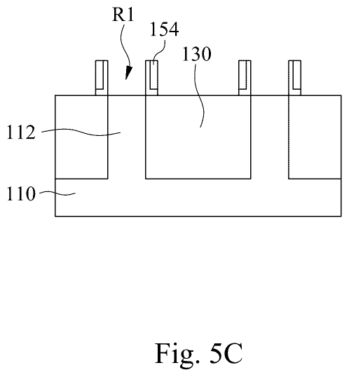

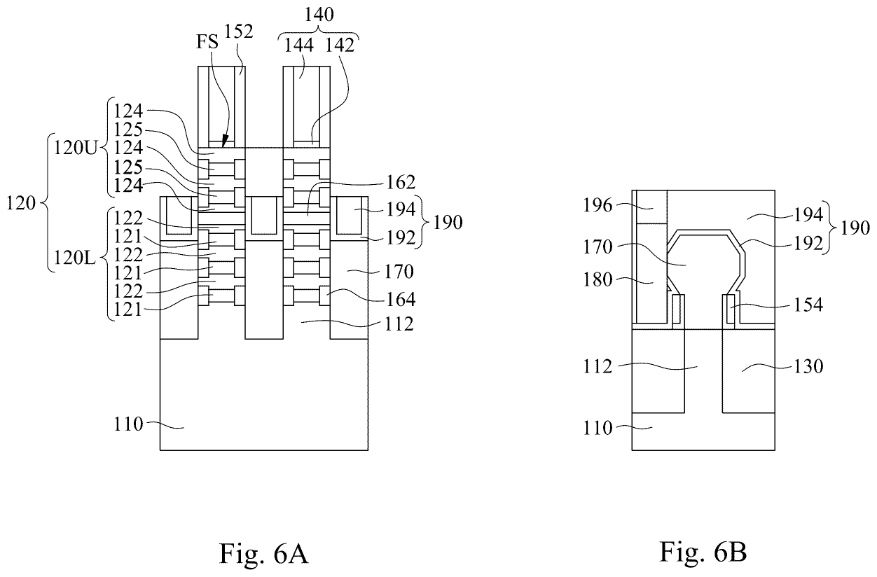

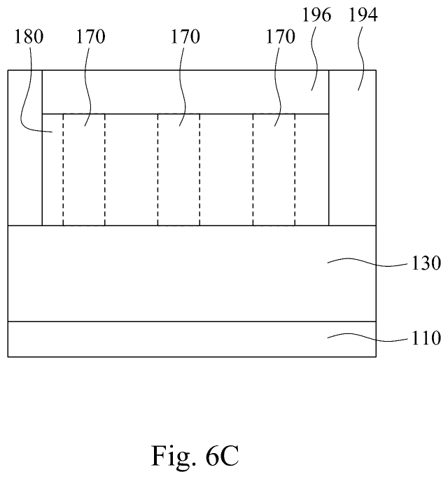

FIGS. 2-9C illustrate schematic cross-sectional views of intermediate stages in the manufacture of an integrated circuit device in accordance with some embodiments of the present disclosure. The manufacture of the integrated circuit device in FIGS. 2-9C shows an example process flow for forming an integrated circuit device including a side connection structure (e.g., the side connection structure SC1 in FIGS. 1A and 1B). FIGS. 2, 4B, 5B, 6A, 7A, 8B, and 9B are cross-sectional views of the integrated circuit device (e.g., taken along line X1-X1 in FIGS. 1A and 1B) at various manufacturing stages in accordance with some embodiments. FIGS. 3, 4A, 5A, 8A, and 9A are cross-sectional views of the integrated circuit device (e.g., taken along line Y1-Y1 in FIGS. 1A and 1B) at various manufacturing stages in accordance with some embodiments. FIGS. 5C, 6B, 7B, and 9C are cross-sectional views of the integrated circuit device (e.g., taken along line Y2 Y2 in FIGS. 1A and 1B) at various manufacturing stages in accordance with some embodiments. FIG. 6C is a cross-sectional view of the integrated circuit device (e.g., taken along line X2-X2 in FIGS. 1A and 1B) at various manufacturing stages in accordance with some embodiments. It is understood that additional steps may be provided before, during, and after the steps shown in FIGS. 2-9C, and some of the steps described below can be replaced or eliminated for additional embodiments of the method. The order of the operations/processes may be interchangeable.

Reference is made to FIG. 2. A stack 120 including a lower epitaxial stack 120L, a middle layer 123, and an upper epitaxial stack 120U are formed over a substrate 110 in a sequence. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120L includes sacrificial layers 121 and channel layers 122 alternately arranged over the substrate 110. The sacrificial layers 121 may have different semiconductor compositions from the channel layers 122. In some embodiments, the semiconductor layer 121 are Si_{y}Ge_{1-y}, and the channel layers 122 are SiₓGe₁₋ₓ, in which x and y are in a range from 0 to 1, and x>y. However, other embodiments are possible including those that provide for the material/compositions having different oxidation rates and/or etch selectivity. In some embodiments, the sacrificial layers 121 include SiGe and the channel layers 122 include Si.

A middle layer 123 is deposited over the stack 120L for spacing the top channel layer in the stack 120U and the bottom channel layers in the stack 120L from each other. The middle layer 123 may include a material different from that of the sacrificial layer 121 and the channel layers 122. In some embodiments, the middle layer 123 may include a semiconductor material, such as SiGe, Ge, or other suitable semiconductor materials with a semiconductor composition different from that of the sacrificial layer 121 and the channel layers 123, in which the middle layer 123 can be replaced with a dielectric material in subsequent process. For example, the sacrificial layer 121 are Si_{y}Ge_{1-y}, and the channel layers 122 are SiₓGe₁₋ₓ, the middle layer 123 are Si_{z}Ge_{1-z}, in which x, y, and z are in a range from 0 to 1, and x>y>z. In some embodiments, the sacrificial layers 121 and the middle layer 123 are SiGe layers, and the middle layer 123 is a SiGe layer having a greater germanium atomic percentage than the sacrificial layers 121. In some alternative embodiments, the middle layer 123 may include a dielectric material, such as silicon nitride, silicon oxide, silicon oxynitride, the like, or the combination thereof.

The epitaxial stack 120U includes channel layers 124 and sacrificial layers 125 alternately arranged over the middle layer 123. The sacrificial layers 125 may have different semiconductor compositions from the channel layers 124. In some embodiments, the semiconductor layer 125 are Si_{y}Ge_{1-y}, and the channel layers 124 are SiₓGe₁₋ₓ, in which x and y are in a range from 0 to 1, and x>y. For example, x is 1, and y is in a range from about 0.2 to about 0.95. However, other embodiments are possible including those that provide for the material/compositions having different oxidation rates and/or etch selectivity. In some embodiments, the sacrificial layers 125 include SiGe and the channel layers 124 include Si. In some alternative embodiments, the sacrificial layers 125 include Si and the channel layers 124 include SiGe. Other details of the epitaxial stack 120U, the sacrificial layers 125, and channel layers 124 are similar to the epitaxial stack 120L, the sacrificial layers 121, and channel layers 122, and not repeated herein.

The channel layers 122 and 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. In some embodiments, a space between adjacent channel layers 122/124 may be in a range from about 2 nanometers to about 30 nanometers. In the present embodiments, the multiple channel layers 122/144 are used. In some alternative embodiments, a single channel layer 122/124 can be used. The use of the channel layers 122 and 124 to define a channel or channels of a device is further discussed below. The channel layers 122 and 124 may be referred to as semiconductor channels in the context.

Reference is made to FIG. 3. One or more semiconductor fins FS extending from the substrate 110 are formed. In various embodiments, each of the fins FS includes a substrate portion 112 formed from the substrate 110, portions of each of the epitaxial layers 121 and 122 of the epitaxial stack 120L, a portion of the middle layer 123, and portions of each of the epitaxial layers 124 and 125 of the epitaxial stack 120U. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120L, the middle layer 123, and the epitaxial stack 120U. The etching process can include dry etching, wet etching, reactive ion etching (RIE), and/or other suitable processes.

An isolation structure 130 is formed in a trench FT around the fins FS. The isolation structure 130 may be a single-layer or a multi-layer structure. In some embodiments, the isolation structure 130 includes low-k dielectric materials, SiN, SiCN, SiOC, SiOCN or the like. Formation of the isolation structure 130 may include depositing a dielectric material over the fins FS, followed by an etching back process. Through the etching back process, a top surface of the isolation structure 130 may be lower than a top surface of the substrate portion 112. In some alternatively embodiments, the top surface of the isolation structure 130 may be higher than the top surface of the substrate portion 112.

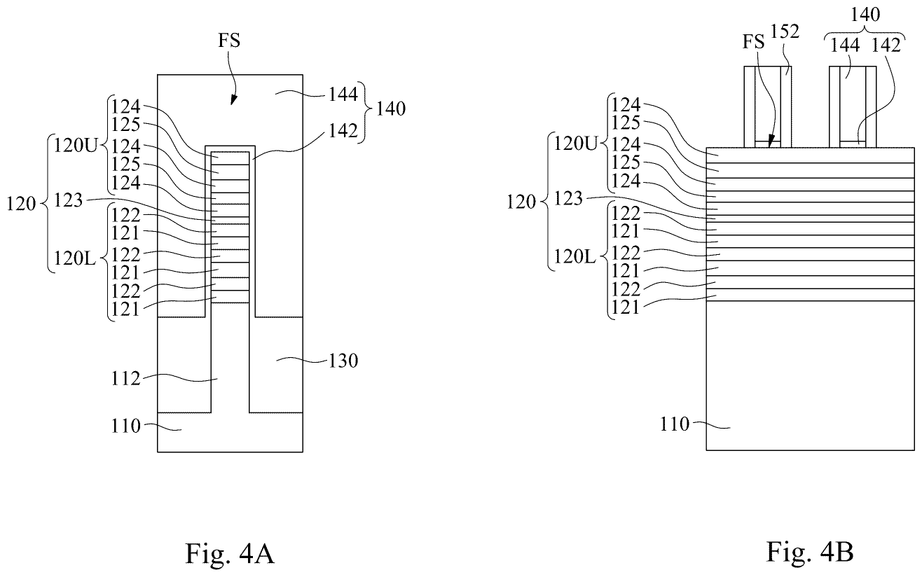

Reference is made to FIGS. 4A and 4B. One or more dummy gate structures 140 are formed on the epitaxial stack 120. The dummy gate structure 140 may include a gate dielectric 142 and a gate electrode 144 over the gate dielectric 142. The gate dielectric 142 may include one or more layers of dielectric material, such as silicon oxide, silicon nitride, a high-k dielectric material, and/or other suitable dielectric material. In some embodiments, the gate electrode 144 includes a material different than that of the gate dielectric 142. In some embodiments, the gate dielectric 142 may be deposited by a CVD process, a sub-atmospheric CVD (SACVD) process, a FCVD process, an ALD process, a PVD process, or other suitable process. The gate electrode 144 may include polycrystalline silicon (polysilicon). In some embodiments, the materials of the dummy gate structure 140 are formed by various processes such as layer deposition, for example, CVD, PVD, ALD, thermal oxidation, or other suitable deposition techniques, or combinations thereof.

The dummy gate structures 140 may be formed by first depositing a blanket gate dielectric layer and a gate electrode layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer and the gate electrode layer, the fins FS are partially exposed on opposite sides of the dummy gate structure 140.

Gate spacers 152 are formed on opposite sidewalls of the dummy gate structures 140. In some embodiments, the spacer 152 includes a single layer or multiple layers. The spacer 152 may be made of a dielectric material such as silicon oxide, silicon nitride, silicon carbide, silicon oxynitride, SiCN, silicon oxycarbide, SiOCN, and/or combinations thereof. The gate spacers 152 may be formed by first depositing one or more conformal spacer material layers and subsequently etching back the one or more spacer material layers to form gate spacers 152. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS, leaving the gate spacers 152 on the vertical surfaces, such as the sidewalls of the dummy gate structures 140.

Reference is made to FIGS. 5A-5C. Exposed portions of the semiconductor fins FS that extend laterally beyond the gate spacers 152 (e.g., in source/drain regions of the fins FS) are etched by using, for example, an anisotropic etching process that uses the dummy gate structures 140 and the gate spacers 152 as an etch mask, resulting in recesses R1 into the semiconductor fins FS and between corresponding dummy gate structures 140. The recesses R1 may extend through the epitaxial layers 121, 122, 124, and 125 and the middle layer 123. After the anisotropic etching, end surfaces of the epitaxial layers 121, 122, 124, and 125 are exposed and aligned with respective outermost sidewalls of the gate spacers 152, due to the anisotropic etching. In some embodiments, the anisotropic etching may be performed by a dry chemical etch (e.g., reactive-ion etching) with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. Fin sidewall spacers 154 on opposite side of the semiconductor fins FS may remain and on opposite sides of the recesses R1.

Inner spacers 164 may be formed on opposite end surfaces of the sacrificial layers 121 and 125. For example, the sacrificial layers 121 and 125 are laterally or horizontally recessed by using suitable selective etching process, resulting in lateral/sidewall recesses R2 vertically between corresponding channel layers 122, and vertically between corresponding channel layers 124. Inner spacers 164 may be formed in the lateral/sidewall recesses R2. The inner spacers 164 may include a low-k dielectric material, such as SiOₓ, SiON, SiOC, SiN, SiCN, or SiOCN. Formation of the inner spacers 164 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left. The inner spacers 164 may include a single layer or multiple layers. The inner spacers 164 may serve to isolate metal gates from source/drain regions formed in subsequent processing.

The middle layer 123 (referring to FIGS. 4A-4B) is replaced with a dielectric layer 162, which may include a dielectric material, such as silicon nitride, silicon oxide, silicon oxynitride, the like, or the combination thereof. In some embodiments, the replacing process including removing the middle layer 123 (referring to FIGS. 4A-4B) by the selective etching process that laterally recessing the sacrificial layers 121 and 125, thereby resulting the opening O1 between the lower epitaxial stack 120L and the upper epitaxial stack 120U. In some embodiments, the dielectric layer 162 may include a same dielectric material as the inner spacer material layer of the inner spacers 164, the dielectric material of the dielectric layer 162 can be deposited along with the deposition process of the inner spacer material layer of the inner spacers 164.

Reference is made to FIGS. 6A-6C. Source/drain epitaxial structures 170 are formed in the recesses R1. In some embodiments, the source/drain epitaxial structures 170 may include Ge, Si, GaAs, AlGaAs, SiGe, GaAsP, SiP, or other suitable material. The source/drain epitaxial structures 170 may be in-situ doped during the epitaxial process by introducing doping species including: p-type dopants, such as boron or BF₂; n-type dopants, such as phosphorus or arsenic; and/or other suitable dopants including combinations thereof. For example, n-type source/drain epitaxial structures may be SiP, SiAs, a combination of SiP and SiAs/SiSb, SiSb, or a combination of SiP, SiAs, and SiSb. For example, p-type source/drain epitaxial structures may be SiB, SiGe, SiGe: B, SiSb, or SiGe: Ga. If the source/drain epitaxial structures 170 are not in-situ doped, an implantation process (i.e., a junction implant process) is performed to dope the source/drain epitaxial structures 170. In some embodiments, the dopant concentration of the source/drain epitaxial structures 170 may be in a range from about 1E21 to about 1E22 atoms/cm³.

The source/drain epitaxial structures 170 may be formed by performing an epitaxial growth process that provides an epitaxial material on the surfaces of the exposed surfaces of the channel layer 122. Suitable epitaxial processes include CVD deposition techniques, molecular beam epitaxy, and/or other suitable processes. The epitaxial growth process may use gaseous and/or liquid precursors, which interact with the composition of semiconductor materials of the channel layer 122. In some embodiments, one or more etching processes may be performed to lower top surfaces of the source/drain epitaxial structures 170. The resulted source/drain epitaxial structures 170 have a top surface lower than that of the channel layer 124. The etching process may be dry etch, wet etch, or the combination thereof.

Dielectric structures 190 are formed over the source/drain epitaxial structures 170. The dielectric structures 190 may include a contact etch stop layer (CESL) 192 and an interlayer dielectric layer (ILD) 194 over the CESL 192. In some examples, the CESL layer 192 includes a silicon nitride layer, silicon oxide layer, a silicon oxynitride layer, and/or other suitable materials having a different etch selectivity than the ILD layer 194. In some embodiments, the ILD layer 254 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

A side connection structure 180 is formed on a side surface of one of the source/drain epitaxial structures 170 and a side surface of another one of the source/drain epitaxial structures 170, thereby establishing an electrical connection therebetween. The side connection structure 180 may include a suitable conductive material, such as doped semiconductor, metal, and/or metal silicide. Formation of the side connection structure 180 may including etching openings in the dielectric structures 190 to expose the side surface of said one of the source/drain epitaxial structures 170 and the side surface of said another one of the source/drain epitaxial structures 170, followed by depositing the suitable conductive material into the openings in the dielectric structures 190. The conductive material may be polished and recessed, and the remaining portion of the conductive material form the side connection structure 180. Another ILD 196 is deposited over the side connection structure 180 for electrical isolation from above conductive features.

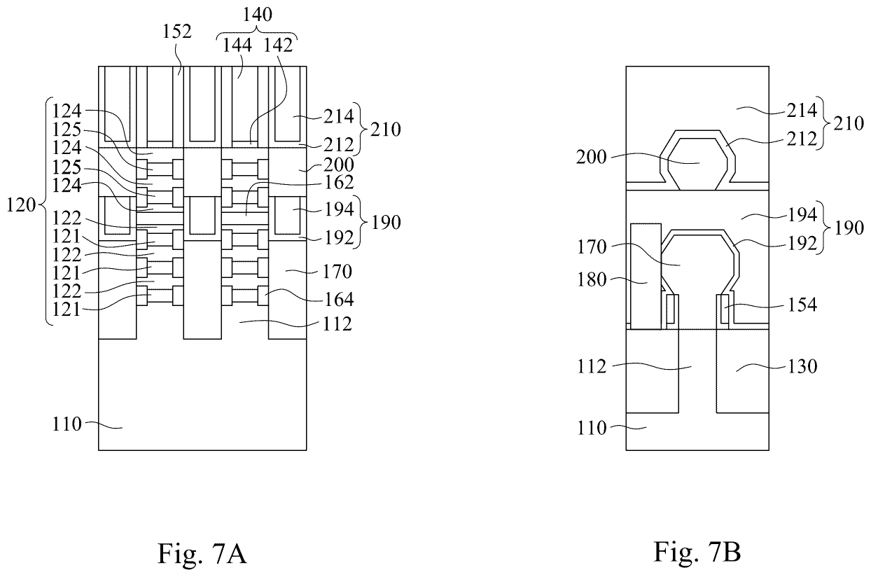

Reference is made to FIGS. 7A-7B. Source/drain epitaxial structures 200 are formed in the recesses R1 on opposite sides of the channel layers 124. The source/drain epitaxial structures 200 may be in contact with the exposed end surfaces of the channel layers 124. In some embodiments, the source/drain epitaxial structures 200 may include Ge, Si, GaAs, AlGaAs, SiGe, GaAsP, SiP, or other suitable material. The source/drain epitaxial structures 200 may be in-situ doped during the epitaxial process by introducing doping species including: p-type dopants, such as boron or BF₂; n-type dopants, such as phosphorus or arsenic; and/or other suitable dopants including combinations thereof. For example, n-type source/drain epitaxial structures may be SiP, SiAs, a combination of SiP and SiAs/SiSb, SiSb, or a combination of SiP, SiAs, and SiSb. For example, p-type source/drain epitaxial structures may be SiB, SiGe, SiGe: B, SiSb, or SiGe: Ga. If the source/drain epitaxial structures 200 are not in-situ doped, an implantation process (i.e., a junction implant process) is performed to dope the source/drain epitaxial structures 200. In some embodiments, the dopant concentration of the source/drain epitaxial structures 200 may be in a range from about 1E21 to about 1E22 atoms/cm³.

The source/drain epitaxial structures 200 may be formed by performing an epitaxial growth process that provides an epitaxial material on the exposed surfaces of the channel layers 124. Suitable epitaxial processes include CVD deposition techniques, molecular beam epitaxy, and/or other suitable processes. The epitaxial growth process may use gaseous and/or liquid precursors, which interact with the composition of semiconductor materials of the channel layers 124.

Dielectric structures 210 are formed over the source/drain epitaxial structures 170. The dielectric structures 210 may include a contact etch stop layer (CESL) 212 and an interlayer dielectric layer (ILD) 214 over the CESL 212. In some examples, the CESL layer 212 includes a silicon nitride layer, silicon oxide layer, a silicon oxynitride layer, and/or other suitable materials having a different etch selectivity than the ILD layer 214. In some embodiments, the ILD layer 214 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

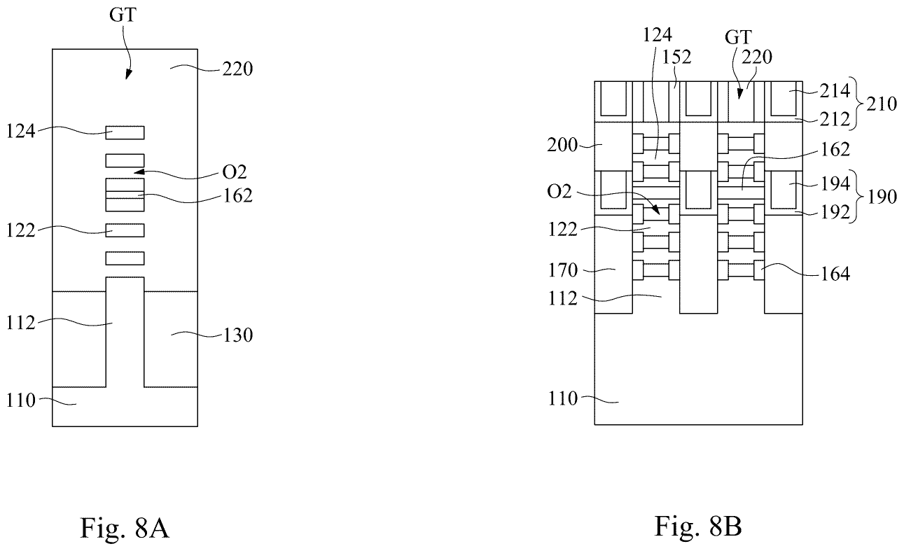

Reference is made to FIGS. 8A and 8B. The dummy gate structure 140 and the sacrificial layer 121 and 125 (referring to FIG. 7A) are replaced with a high-k/metal gate structure 220. For example, the dummy gate structures 140 (referring to FIG. 7A) are removed to leave gate trenches GT between the gate spacers 152, followed by removing the sacrificial layers 121 and 125 (referring to FIG. 7A) to leave openings O2 between the channel layers 122 and between the channel layers 124. Subsequently, the replacement gate structures 220 are respectively formed in the gate trenches GT to surround each of the nanosheets 122 and 124 suspended in the gate trenches GT. The gate structures 220 may be final gates of GAA FETs. The final gate structure may be a high-k/metal gate stack, however other compositions are possible. In some embodiments, each of the gate structures 220 forms the gate associated with the multi-channels provided by the plurality of nanosheets 122 and 124. For example, the high-k/metal gate structures 220 are formed within the openings/spaces O2 provided by the release of nanosheets 122 and 124.

In various embodiments, the high-k/metal gate structure 220 includes a gate dielectric layer formed around the nanosheets 124 and 124 and a gate metal layer formed around the dielectric layer and filling a remainder of gate trenches GT. The gate dielectric layer may include an interfacial layer and a high-k gate dielectric layer over the interfacial layer. The gate metal layer may include one or more work function metal layers stacked one over another and a fill metal filling up a remainder of gate trenches GT. Formation of the high-k/metal gate structures 220 may include one or more deposition processes to form various gate materials, followed by a CMP processes to remove excessive gate materials, resulting in the high-k/metal gate structures 220 having top surfaces level with a top surface of the dielectric material 210. Thus, transistors (e.g., GAA FET) are formed, and the high-k/metal gate structure 220 surrounds each of the nanosheets 122 and 124, and thus is referred to as a gate of the transistors (e.g., GAA FET).

Reference is made to FIGS. 9A-9C. A front-side multilayer interconnection (MLI) structure FI may be formed over a frontside of the device. The front-side MLI structure FI may include a plurality of front-side metallization layers. The number of front-side metallization layers may vary according to design specifications of the integrated circuit. The front-side metallization layers each comprise a front-side inter-metal dielectric (IMD) layer FD, one or more horizontal interconnects, such as front-side metal lines ML, respectively extending horizontally or laterally in the front-side IMD layer FD, and vertical interconnects, such as front-side conductive vias FV, respectively extending vertically in the front-side IMD layer FD.

Prior to the formation of the front-side MLI structure FI, one or more front-side contact FC may be formed over the source/drain epitaxial structures 170. The front-side contact FC may be formed by depositing a dielectric layer FCD over the dielectric structures 210 and etching openings in the dielectric layer FCD and the dielectric structures 210 to expose top surfaces of the source/drain epitaxial structures 170, followed by depositing metals into the openings and a planarization process. The front-side metal lines ML of the front-side multilayer interconnection MLI may be in contact with the front-side contact FC.

And, a back-side multilayer interconnection BMLI structure BI may be formed over a backside of the device. The back-side MLI structure BI may include a plurality of back-side metallization layers. The number of back-side metallization layers may vary according to design specifications of the integrated circuit. The back-side metallization layers each comprise a back-side inter-metal dielectric (IMD) layer BD, one or more horizontal interconnects, such as back-side metal lines BML, respectively extending horizontally or laterally in the back-side IMD layer BD, and vertical interconnects, such as back-side conductive vias BV, respectively extending vertically in the back-side IMD layer BD.

Prior to the formation of the back-side MLI structure BI, one or more back-side contacts BC may be formed over a backside of the source/drain epitaxial structures 170. The back-side contact BC may be formed by depositing a dielectric layer BCD and etching openings in the dielectric layer BCD and the dielectric structures 210 to expose back surfaces of the source/drain epitaxial structures 170, followed by depositing metals into the openings and a planarization process. The back-side metal lines BML of the back-side MLI structure BI may be in contact with the back-side contact BC.

In some embodiments, the side connection structure 180 may be spaced apart from the front-side MLI structure FI and the back-side MLI structure BI, for example, by the ILD 196 and the isolation structure 130. The side connection structure 180 provide electrical connection between transistors without using the interconnects of the front-side MLI structure FI and the interconnects of the back-side MLI structure BI. In the context, the side connection structure 180 may serve as the side connection structure SC1 in FIGS. 1A and 1B. The high-k/metal gate structure 220 may serve as the gate structures 12B and 12T in FIGS. 1A and 1B. The source/drain epitaxial structures 170 may serve as the source/drain regions 13B and the source/drain epitaxial structure of the source/drain conductive structure 14B in FIGS. 1A and 1B. The back-side contact BC may serve as the source/drain contact of the source/drain conductive structure 14B in FIGS. 1A and 1B. And, the source/drain epitaxial structures 200 may serve as the source/drain regions 13T and the source/drain epitaxial structure of the source/drain conductive structure 14T in FIGS. 1A and 1B. The front-side contact FC may serve as the source/drain contact of the source/drain conductive structure 14T in FIGS. 1A and 1B.

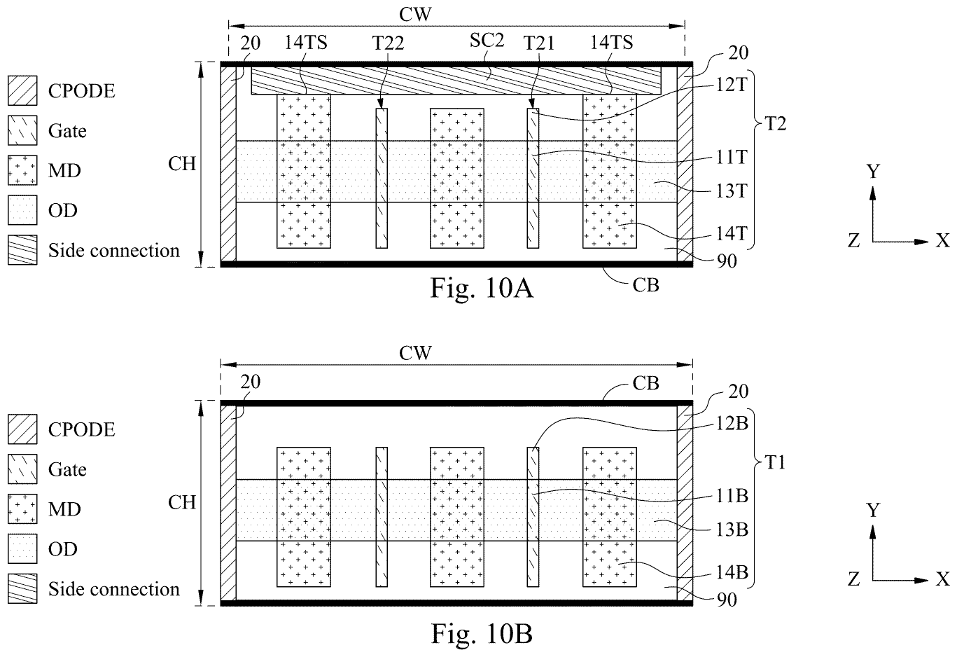

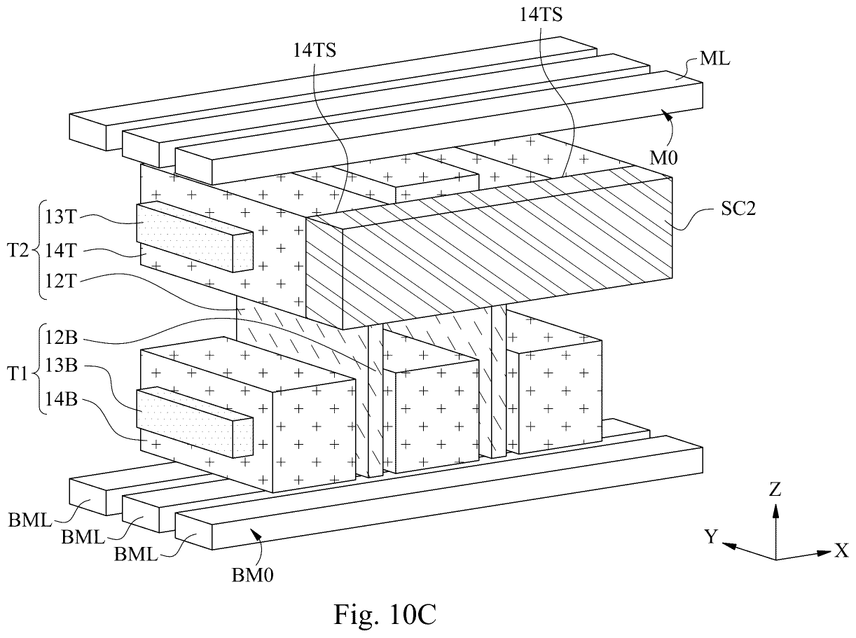

FIGS. 10A and 10B are respectively layout diagrams of upper and lower portions of an integrated circuit device in accordance with some embodiments of the present disclosure. FIG. 10C is a perspective view of an integrated circuit device according to the layout diagrams in FIGS. 10A and 10B. Details of the present embodiments are similar to those of FIGS. 1A-1C, except that the integrated circuit device includes a side connection structure SC2 configured to establish an electrical connection between the two source/drain conductive structures 14T of the top transistors T2, rather than the side connection structure SC1 (referring to FIGS. 1A-1C). The side connection structure SC2 may also be denoted as “Side connection” in the drawings. For example, in FIGS. 10B and 10C, the side connection structure SC2 is in contact with a lateral side 14TS of one of the source/drain conductive structures 14T and a lateral side 14TS of another one of the source/drain conductive structures 14T. The side connection structure SC2 may extend substantially along the direction the same as that of the active regions, such as the direction X. And, the side connection structure SC2 may include a suitable conductive material, such as doped semiconductor, metal, and/or metal silicide.

Through the configuration, the side connection structure SC2 electrically connects the source/drain conductive structure 14T of the transistor T21 to the source/drain conductive structure 14T of the transistor T22. The active layer of the transistor T21 is aligned with the active layer of the transistor T22 substantially along the direction X. And, the gate structure 12T of the transistors T21 and T22 are spaced apart from the side connection structure SC1. Other details of the present embodiments are similar to those illustrated above, and therefore not repeated herein.

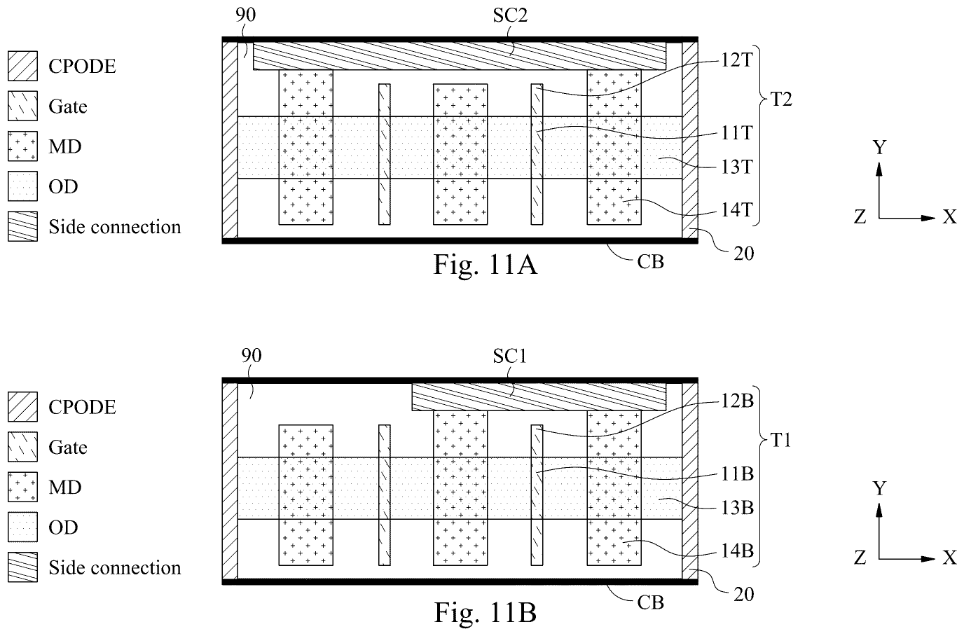

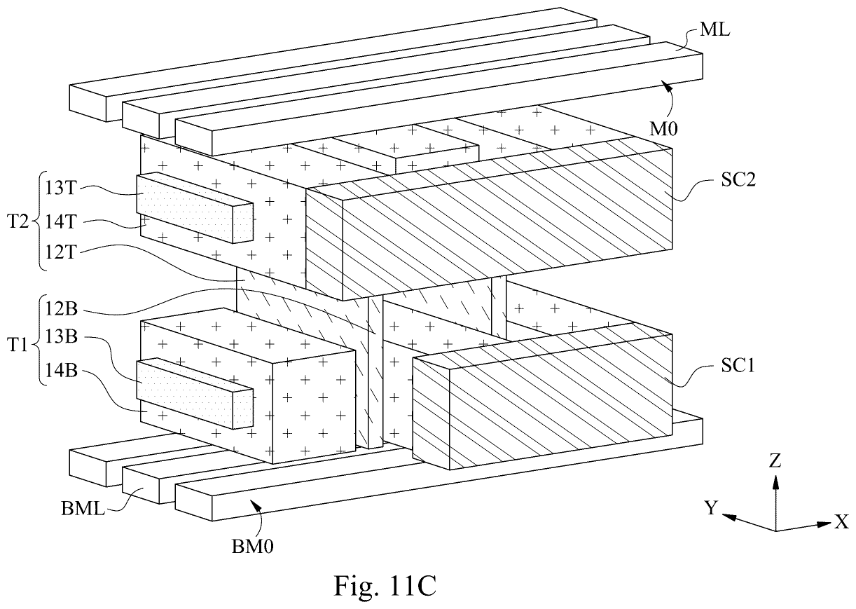

FIGS. 11A and 11B are respectively layout diagrams of upper and lower portions of an integrated circuit device in accordance with some embodiments of the present disclosure. FIG. 11C is a perspective view of an integrated circuit device according to the layout diagrams in FIGS. 11A and 11B. Details of the present embodiments are similar to those of FIGS. 1A-1C and FIGS. 10A-10C, except that the integrated circuit device include both the side connection structure SC1 and the side connection structure SC2. As aforementioned, the side connection structure SC1 is configured to establish an electrical connection between the two source/drain conductive structures 14B of the bottom transistors T1, and the side connection structure SC2 is configured to establish an electrical connection between the two source/drain conductive structures 14T of the top transistors T2. In the present embodiments, the side connection structure SC1 and the side connection structure SC2 may be electrically isolated from each other. And, the side connection structure SC1 and the side connection structure SC2 may overlap with each other along a vertical direction Z, which is orthogonal to the directions X and Y. Other details of the present embodiments are similar to those illustrated above, and therefore not repeated herein.

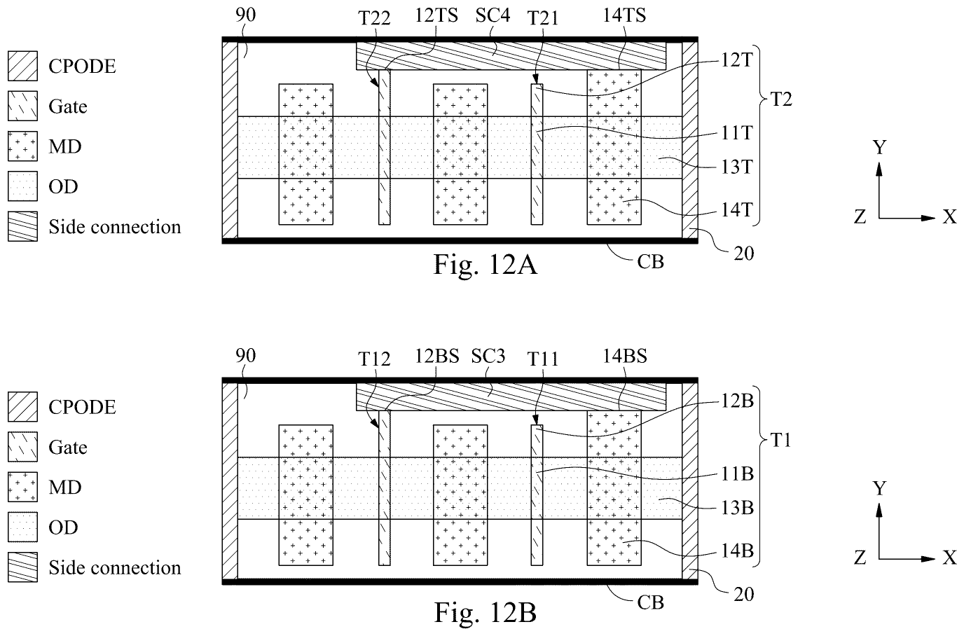

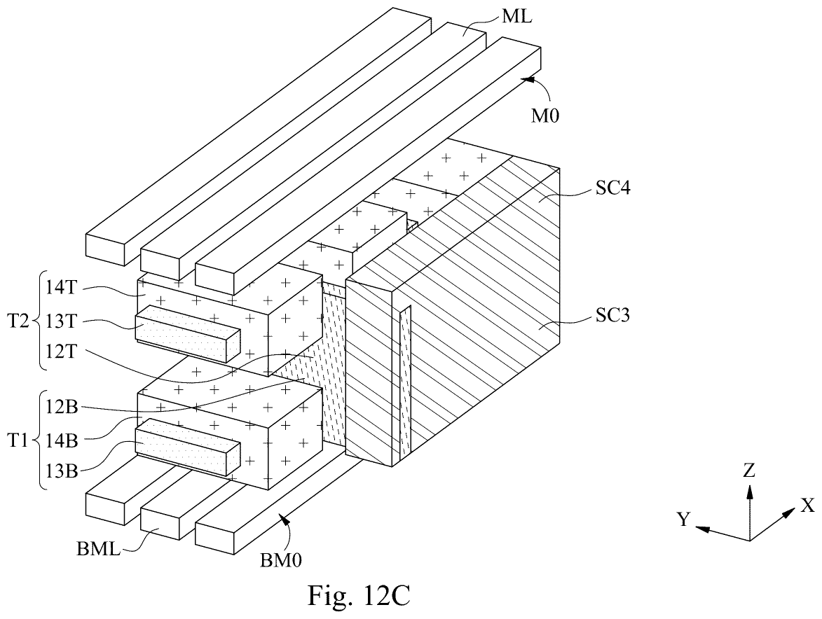

FIGS. 12A and 12B are respectively layout diagrams of upper and lower portions of an integrated circuit device in accordance with some embodiments of the present disclosure. FIG. 12C is a perspective view of an integrated circuit device according to the layout diagrams in FIGS. 12A and 12B. Details of the present embodiments are similar to those of FIGS. 1A-1C, except that the integrated circuit device includes a side connection structure SC3 and/or a side connection structure SC4. The side connection structures SC3 is configured to establish an electrical connection between one of the source/drain conductive structures 14B and one of the gate structures 12B of the bottom transistors T1. The side connection structures SC4 is configured to establish an electrical connection between one of the source/drain conductive structures 14T and one of the gate structures 12T of the top transistors T2. The side connection structures SC3 and SC4 may also be denoted as “Side connection” in the drawings. The side connection structures SC3 and SC4 may extend substantially along the direction the same as that of the active regions, such as the direction X. And, the side connection structures SC3 and SC4 may include a suitable conductive material, such as doped semiconductor, metal, and/or metal silicide.

For example, in FIGS. 12A and 12C, the side connection structure SC4 is in contact with a lateral side 14TS of one of the source/drain conductive structures 14T and a lateral end 12TS of one of the gate structures 12T. In FIGS. 12B and 12C, the side connection structure SC3 is in contact with a lateral side 14BS of one of the source/drain conductive structures 14B and a lateral end 12BS of one of the gate structures 12B. The side connection structure SC3 may be aligned with the side connection structure SC4 along the direction Z. In the present embodiments, the side connection structure SC3 is electrically and physically connected with the side connection structure SC4. In some other embodiments, the side connection structure SC3 is electrically and physically isolated from the side connection structure SC4.

Through the configuration, the side connection structure SC3 electrically connects the source/drain conductive structure 14B of the transistor T11 to the gate structure 12B of the transistor T12, in which the active layer of the transistor T11 is aligned with the active layer of the transistor T12 substantially along the direction X. And, the side connection structure SC4 electrically connects the source/drain conductive structure 14T of the transistor T21 to the gate structure 12T of the transistor T22, in which the active layer of the transistor T21 is aligned with the active layer of the transistor T22 substantially along the direction X. Other details of the present embodiments are similar to those illustrated above, and therefore not repeated herein.

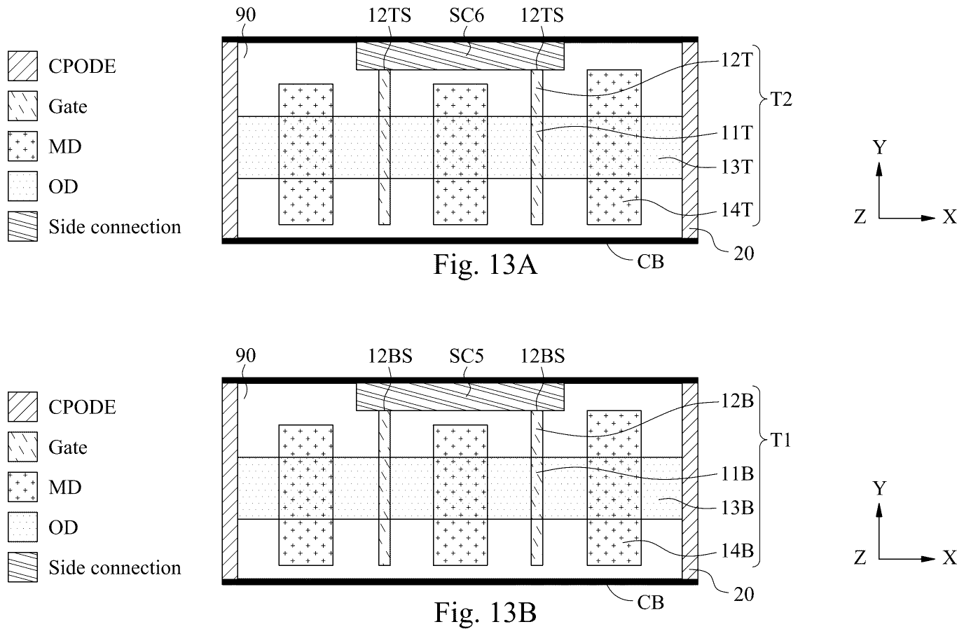

FIGS. 13A and 13B are respectively layout diagrams of upper and lower portions of an integrated circuit device in accordance with some embodiments of the present disclosure. FIG. 13C is a perspective view of an integrated circuit device according to the layout diagrams in FIGS. 13A and 13B. Details of the present embodiments are similar to those of FIGS. 1A-1C, except that the integrated circuit device includes a side connection structure SC5 and/or a side connection structure SC6. The side connection structure SC5 is configured to establish an electrical connection between two gate structures 12B of the bottom transistors T1. The side connection structure SC6 is an electrical connection between two gate structures 12T of the top transistors T2. The side connection structures SC5 and SC6 may also be denoted as “Side connection” in the drawings. The side connection structures SC5 and SC6 may extend substantially along the direction the same as that of the active regions, such as the direction X. And, the side connection structures SC5 and SC6 may include a suitable conductive material, such as doped semiconductor, metal, and/or metal silicide.

For example, in FIGS. 13A and 13C, the side connection structure SC6 is in contact with a lateral end 12TS of one of the gate structures 12T and a lateral end 12TS of another one of the gate structures 12T. In FIGS. 13B and 13C, the side connection structure SC5 is in contact with a lateral end 12BS of one of the gate structures 12B and a lateral end 12BS of another one of the gate structures 12B. The side connection structure SC5 may be aligned with the side connection structure SC6 along the direction Z. In the present embodiments, the side connection structure SC5 is electrically and physically connected with the side connection structure SC6. In some other embodiments, the side connection structure SC5 is electrically and physically isolated from the side connection structure SC6.

Through the configuration, the side connection structure SC5 electrically connects the gate structure 12B of the transistor T11 to the gate structure 12B of the transistor T12, in which the active layer of the transistor T11 is aligned with the active layer of the transistor T12 substantially along the direction X. And, the side connection structure SC6 electrically connects the gate structure 12T of the transistor T21 to the gate structure 12T of the transistor T22, in which the active layer of the transistor T21 is aligned with the active layer of the transistor T22 substantially along the direction X. Other details of the present embodiments are similar to those illustrated above, and therefore not repeated herein.

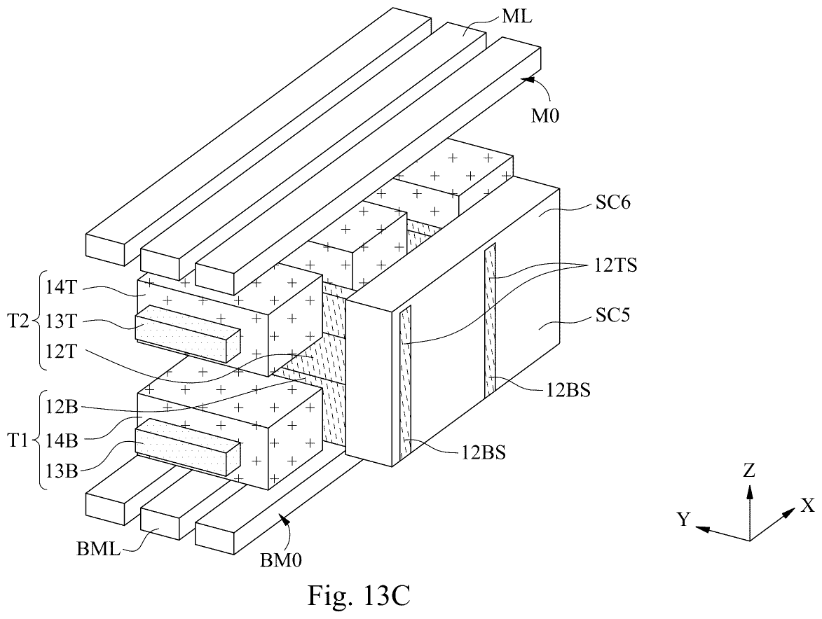

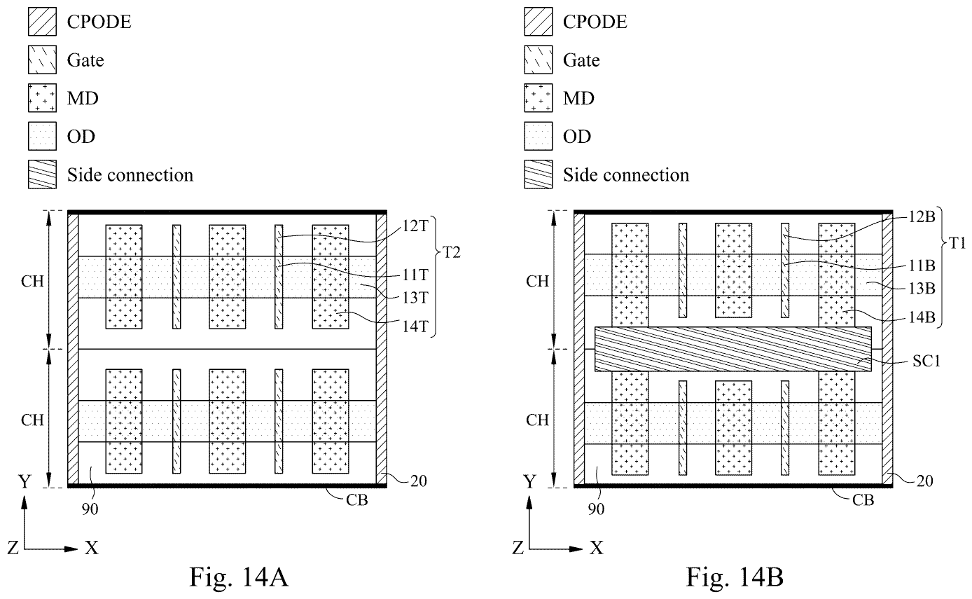

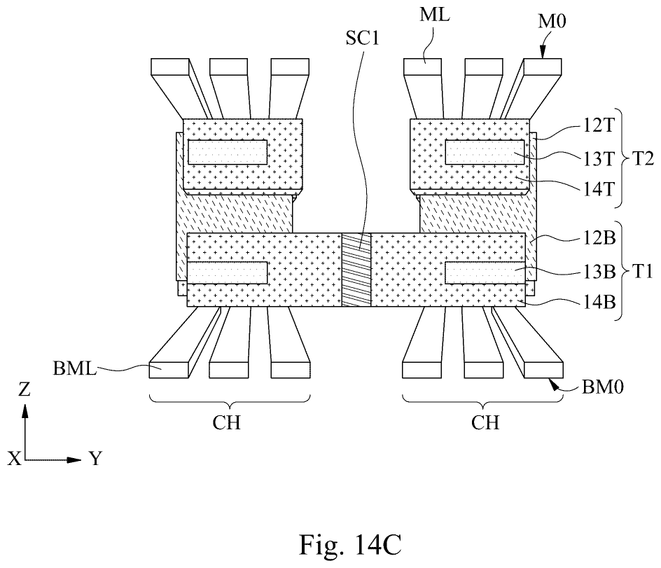

FIGS. 14A and 14B are respectively layout diagrams of upper and lower portions of an integrated circuit device in accordance with some embodiments of the present disclosure. FIG. 14C is a perspective view of an integrated circuit device according to the layout diagrams in FIGS. 14A and 14B. Details of the present embodiments are similar to those of FIGS. 1A-1C, except that of the side connection structure SC1 of two adjacent cells abuts each other, and the side connection structure SC1 of two adjacent cells are electrically connected to each other. Other details of the present embodiments are similar to those illustrated above, and therefore not repeated herein.

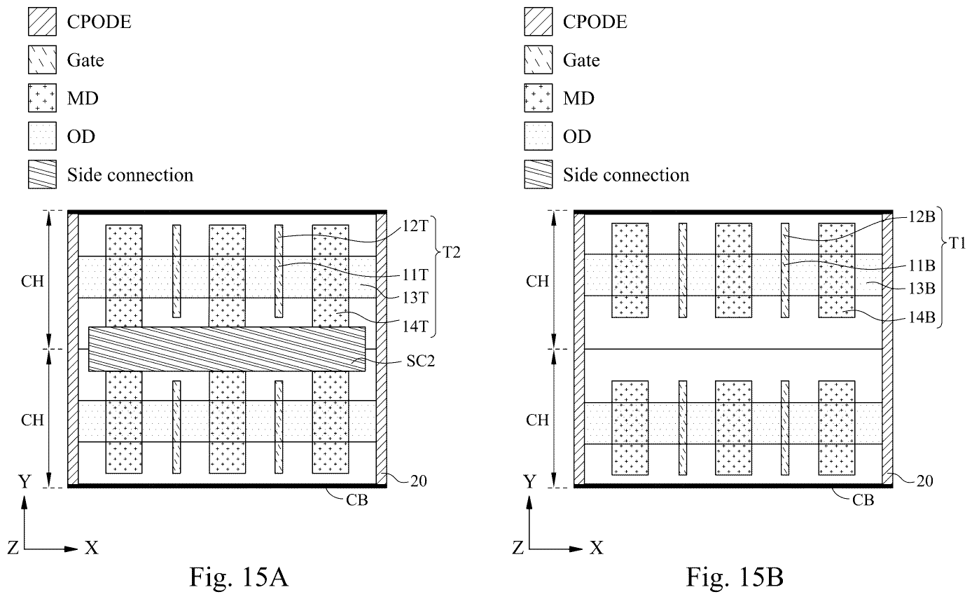

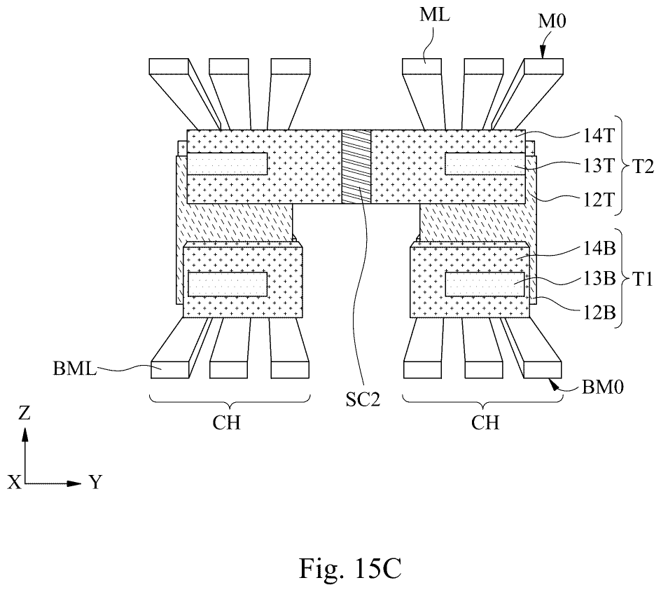

FIGS. 15A and 15B are respectively layout diagrams of upper and lower portions of an integrated circuit device in accordance with some embodiments of the present disclosure. FIG. 15C is a perspective view of an integrated circuit device according to the layout diagrams in FIGS. 15A and 15B. Details of the present embodiments are similar to those of FIGS. 10A-10C, except that of the side connection structure SC2 of two adjacent cells abuts each other, and the side connection structure SC2 of two adjacent cells are electrically connected to each other. Other details of the present embodiments are similar to those illustrated above, and therefore not repeated herein.

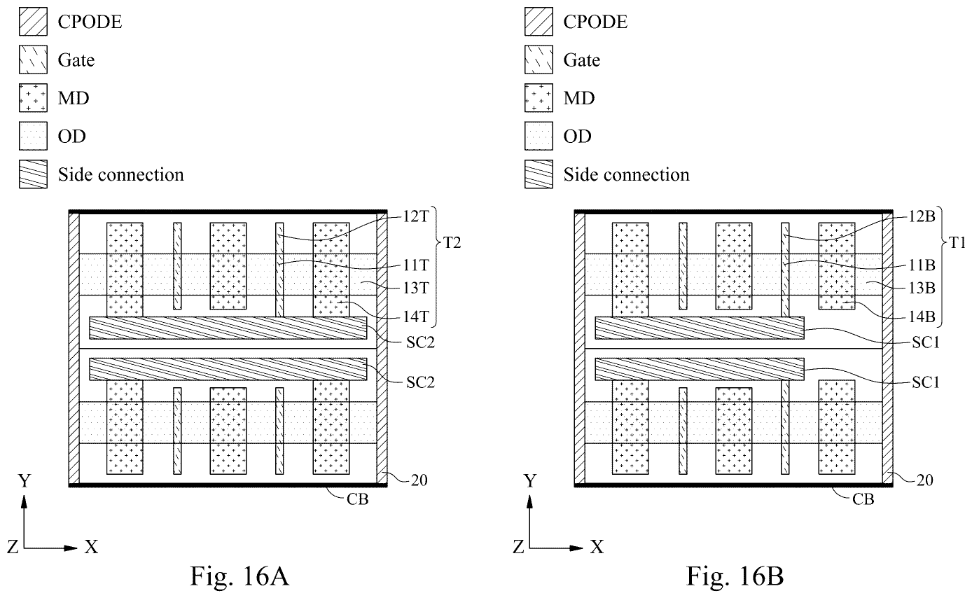

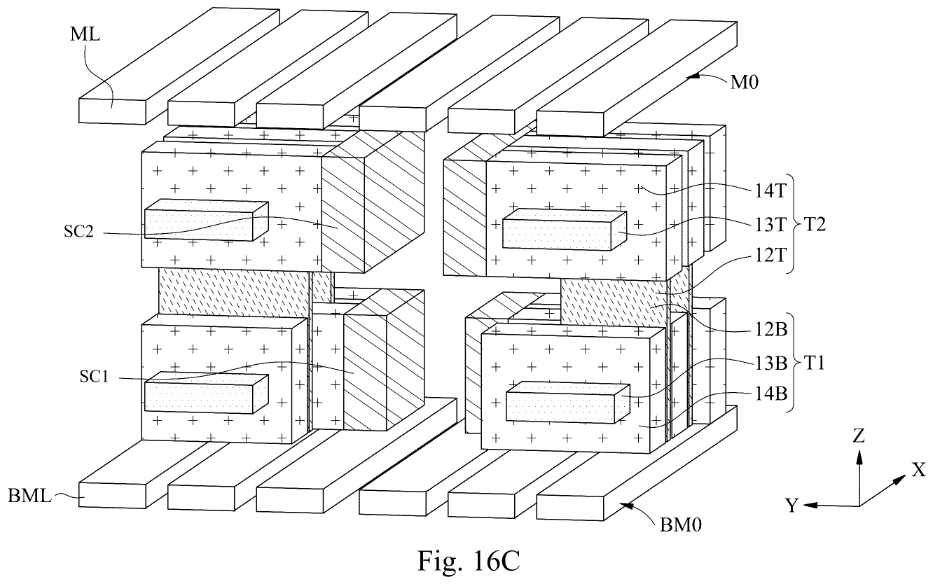

FIGS. 16A and 16B are respectively layout diagrams of upper and lower portions of an integrated circuit device in accordance with some embodiments of the present disclosure. FIG. 16C is a perspective view of an integrated circuit device according to the layout diagrams in FIGS. 16A and 16B. Details of the present embodiments are similar to those of FIGS. 11A-11C, except that of the side connection structure SC2 of two adjacent cells abuts each other, and the side connection structure SC2 of two adjacent cells are electrically isolated to each other. And, the side connection structure SC1 of two adjacent cells abuts each other, and the side connection structure SC1 of two adjacent cells are electrically isolated to each other. Other details of the present embodiments are similar to those illustrated above, and therefore not repeated herein.

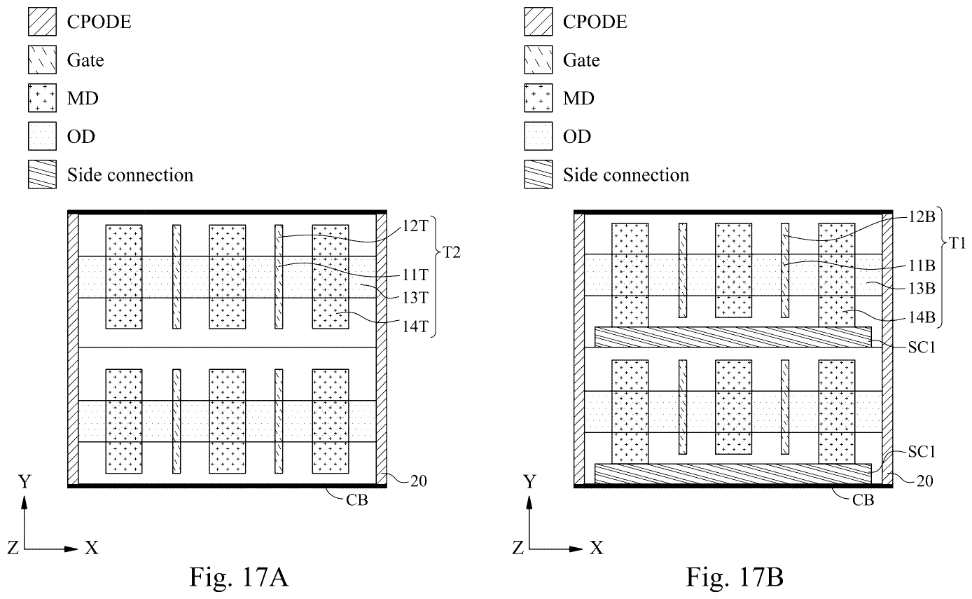

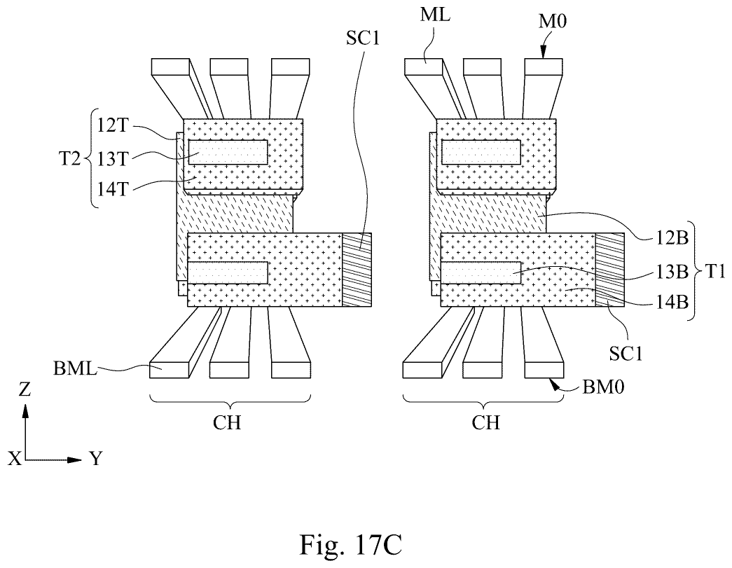

FIGS. 17A and 17B are respectively layout diagrams of upper and lower portions of an integrated circuit device in accordance with some embodiments of the present disclosure. FIG. 17C is a perspective view of an integrated circuit device according to the layout diagrams in FIGS. 17A and 17B. Details of the present embodiments are similar to those of FIGS. 1A-1C, except that of the side connection structure SC1 of two adjacent cells do not abuts each other, and the side connection structure SC1 of two adjacent cells are electrically isolated from each other. Other details of the present embodiments are similar to those illustrated above, and therefore not repeated herein.

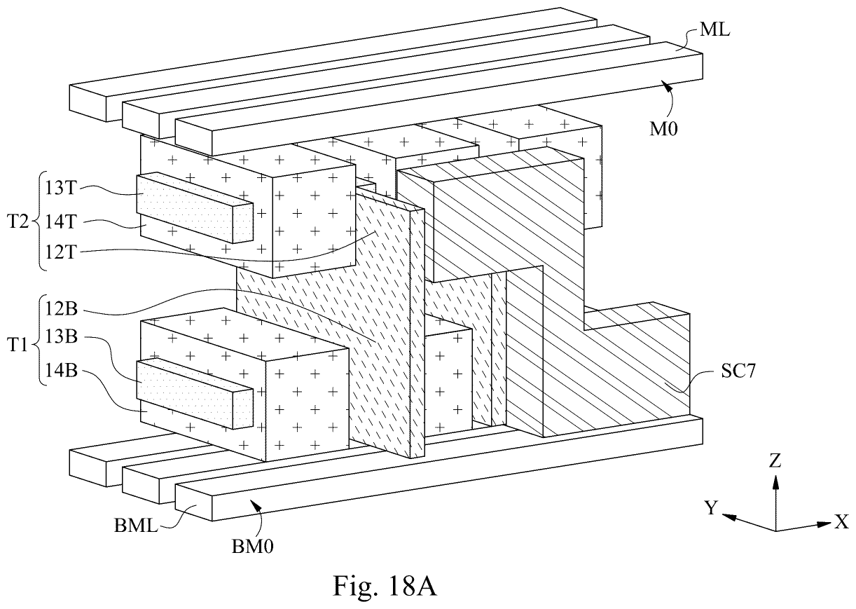

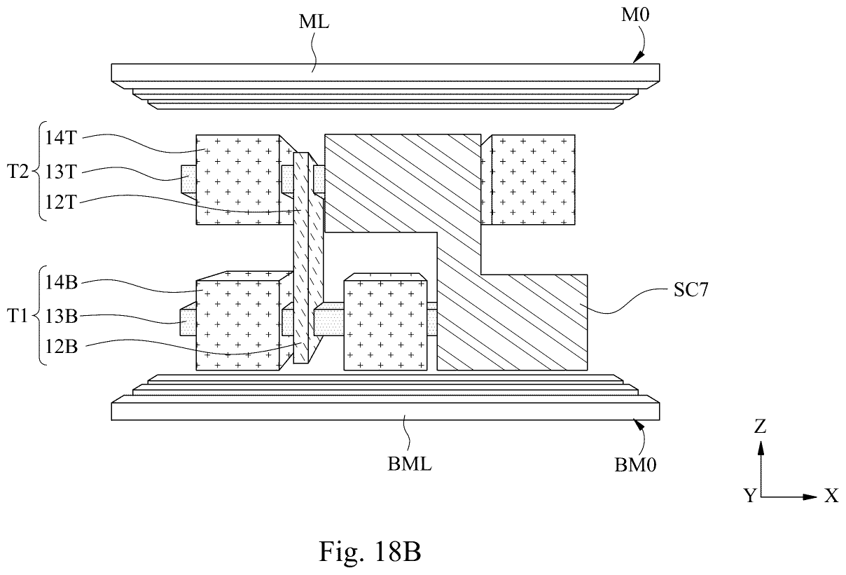

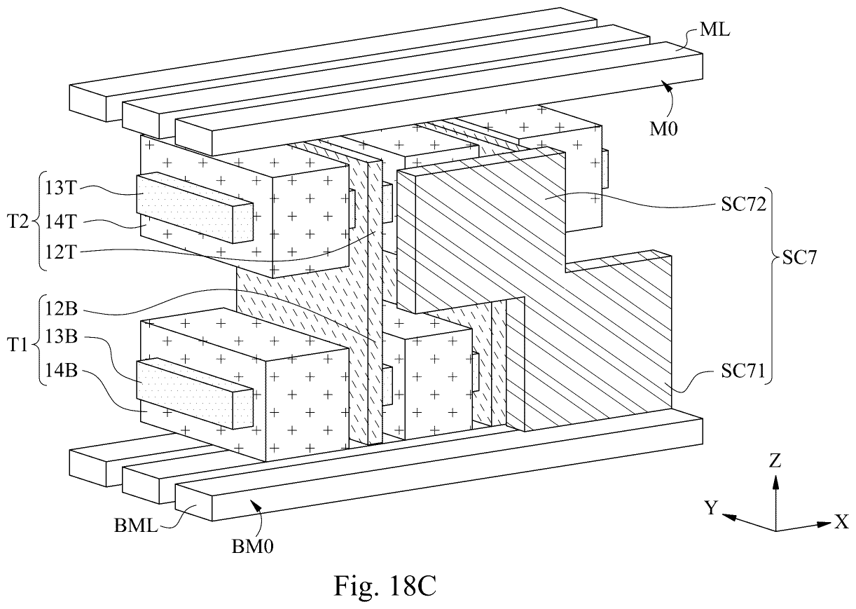

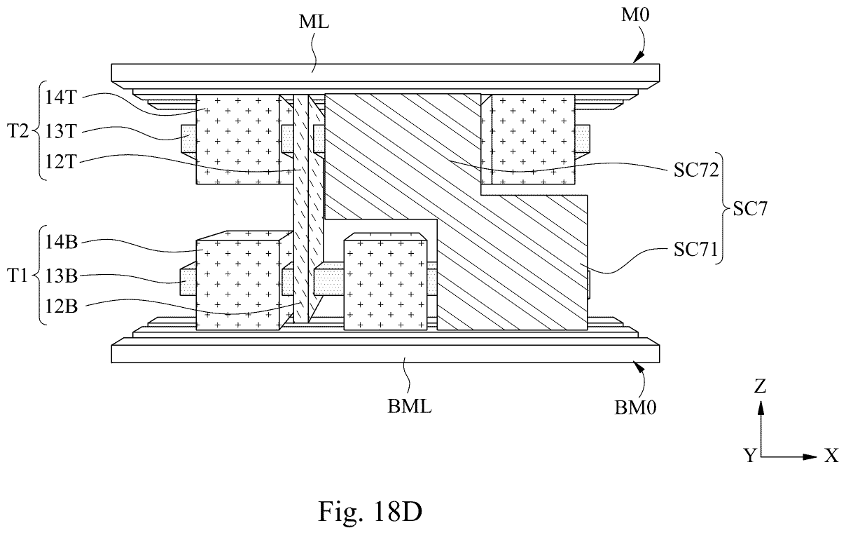

FIGS. 18A and 18B are perspective views of upper and lower portions of an integrated circuit device in accordance with some embodiments of the present disclosure. Details of the present embodiments are similar to those of FIGS. 1A-1C, except that the integrated circuit device includes a side connection structure SC7 extending in both the directions X and Z. The side connection structures SC7 is configured to establish an electrical connection between one of the gate structures 12B and the source/drain conductive structures 14B of the bottom transistors T1 and one of the gate structures 12T and the source/drain conductive structures 14T of the top transistors T2. The side connection structure SC7 may include a suitable conductive material, such as doped semiconductor, metal, and/or metal silicide. The side connection structures SC7 may have a first portion SC71 in contact with the source/drain conductive structures 14B, a second portion SC72 in contact with the source/drain conductive structures 14T, and a third portion SC73 connecting the first portion SC71 to the second portion SC72. In the present embodiments, a top surface of the first portion SC71 is lower than and spaced apart from a bottom surface of the third portion SC73, and the third portion SC73 is connected between the top surface of the first portion SC71 and the bottom surface of the third portion SC73. Other details of the present embodiments are similar to those illustrated above, and therefore not repeated herein.

FIGS. 18C and 18D are perspective views of upper and lower portions of an integrated circuit device in accordance with some embodiments of the present disclosure. Details of the present embodiments are similar to those of FIGS. 18A-18B, except that the second portion SC72 of the side connection structures SC7 is omitted, and the top surface of the first portion SC71 is in contact with the bottom surface of the third portion SC73 Other details of the present embodiments are similar to those illustrated above, and therefore not repeated herein.

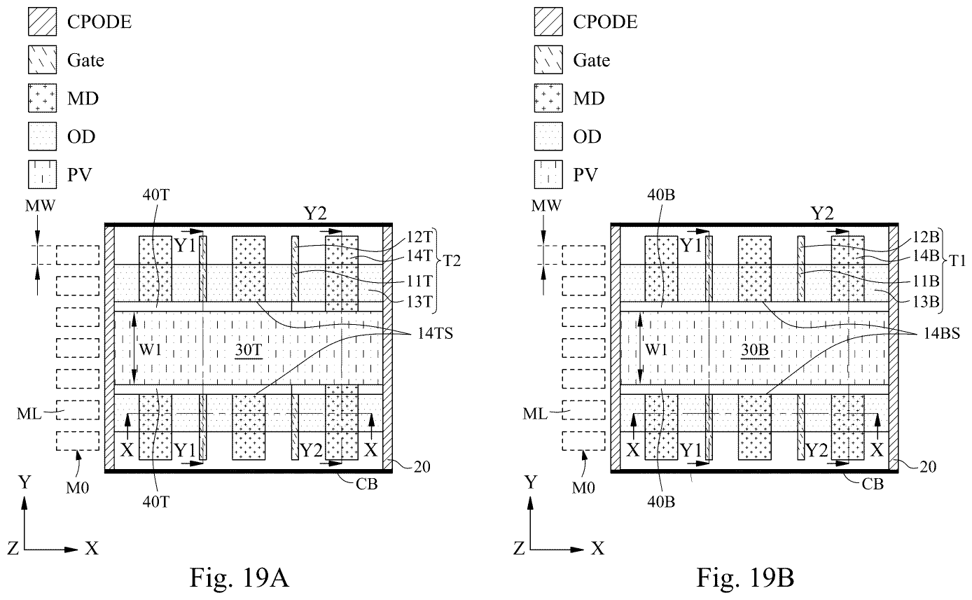

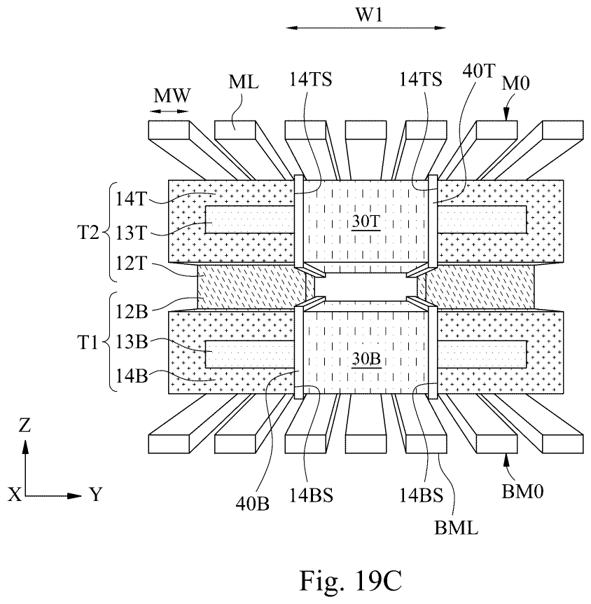

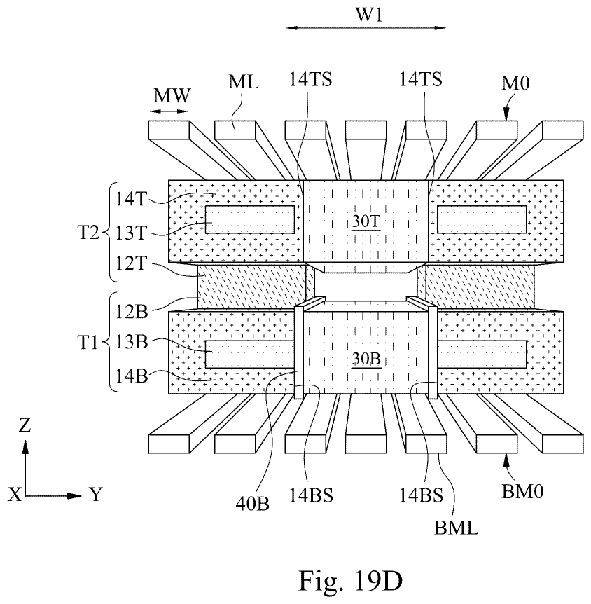

FIGS. 19A and 19B are respectively layout diagrams of upper and lower portions of an integrated circuit device in accordance with some embodiments of the present disclosure. FIGS. 19C and 19D are perspective views of an integrated circuit device according to the layout diagrams in FIGS. 19A and 19B. As described previously, the integrated circuit device may include one or plural CFET structures, each of the CFET structures includes a bottom transistor TR1 and a top transistor TR2 vertically stacked over the bottom transistor TR1. In some embodiments, the top gate structure 12T can be electrically isolated from the bottom gate structure 12B by dielectric bonding materials (not shown), in which a dielectric bonding layer may separate the top gate structure 12T from the bottom gate structure 12B. In some other embodiments, the top gate structure 12T and the bottom gate structure 12B may share a continuous gate structure, such that the top gate structure 12T is electrically connected with the bottom gate structure 12B.

In the layout diagrams of FIGS. 19A and 19B, the active regions, also referred to as oxide-diffusion regions, denoted as “OD” in the context, extend substantially along the direction X. The active region may include one or more channel regions 11T/11B and one or more source/drain regions 13T/13B. The gate structures 12T and 12B, denoted as “Gate”, extend in the direction Y. The gate structures can be high-k/metal gate structures. Source/drain conductive structure, denoted as “MD”, surrounds and connects the source/drain region 13T/13B of the transistors TR 2/TR1. In the layout diagrams of FIGS. 19A and 19B, dielectric gates 20 are located at the two boundary lines oriented along the direction Y. The dielectric gate 20 may be referred to as continuous polysilicon on oxide diffusion edge (CPODE), denoted as “CPODE.”

Power conductive features 30B and 30T, denoted as “PV”, extend substantially along a same direction as that of the active regions (OD) extend along, for example, the direction X. The power conductive features 30B and 30T may be referred to as power rivers. The power conductive features 30B and 30T are respectively located between two adjacent active regions (OD). For example, the power conductive feature 30B is located between every two adjacent active regions (e.g., every two adjacent source/drain conductive structures 14B and every two adjacent channel regions 11B). And, the power conductive feature 30T is located between every two adjacent active regions (e.g., every two adjacent source/drain conductive structures 14A and every two adjacent channel regions 11A). The power conductive features 30A and 30B may include a suitable conductive material, such as doped semiconductor, metal, and/or metal silicide.

Each of the power conductive features 30B and 30T may be electrically connected to a high power voltage source or a low power voltage source. In some embodiments where a NMOS is stacked over a PMOS, the power conductive feature 30T may be electrically connected to a low power voltage source and referred to as a Vss power conductive feature, and the power conductive feature 30B may be electrically connected to a high power voltage source and referred to as a Vdd power conductive feature. In some embodiments where a PMOS is stacked over a NMOS, the power conductive feature 30T may be electrically connected to a high power voltage source and referred to as a Vdd power conductive feature, and the power conductive feature 30B may be electrically connected to a low power voltage source and referred to as a Vss power conductive feature. The power conductive features 30B and 30T may be laterally aligned with the source/drain conductive structures 14B of the bottom transistors T1 and the source/drain conductive structures 14T of the top transistors T2, respectively.

Isolation layers 40T/40B are configured to space and electrically isolate the power conductive feature 30T/30B from some of the transistors, and allow the electrical connection between the others of the transistors and the power conductive feature 30T/30B. In some embodiments, a first portion of the source/drain conductive structures 14T may be in contact with the power conductive feature 30T, and a second portion of the source/drain conductive structures 14T may be spaced apart from the power conductive feature 30T by the isolation layers 40T. In some embodiments, a first portion of the source/drain conductive structures 14B may be in contact with the power conductive feature 30B, and a second portion of the source/drain conductive structures 14B may be spaced apart from the power conductive feature 30B by the isolation layers 40B. The isolation layers 40T/40B may be made of suitable dielectric materials, such as silicon oxide, silicon nitride, silicon oxynitride, the like, or the combination thereof.

Through the configuration of the power conductive features 30T and 30B, some transistors may be electrically connected to the high power voltage source (e.g., through the power conductive feature 30B), while other transistors may be electrically connected to the low power voltage source (e.g., through the power conductive feature 30T).

The power conductive features 30T and 30B may have a width W1 measured along the direction Y, and the metal lines ML of the metallization layer M0 may have a width MW measured along the direction Y. The width W1 of the power conductive features 30T and 30B may be greater than that of the width MW of the metal lines ML of the metallization layer M0. For example, in the present embodiments, a ratio between the width W1 of the power conductive features 30T and 30B and the width MW of the metal lines ML of the metallization layer M0 may be in a range from about 2.5 to about 5.

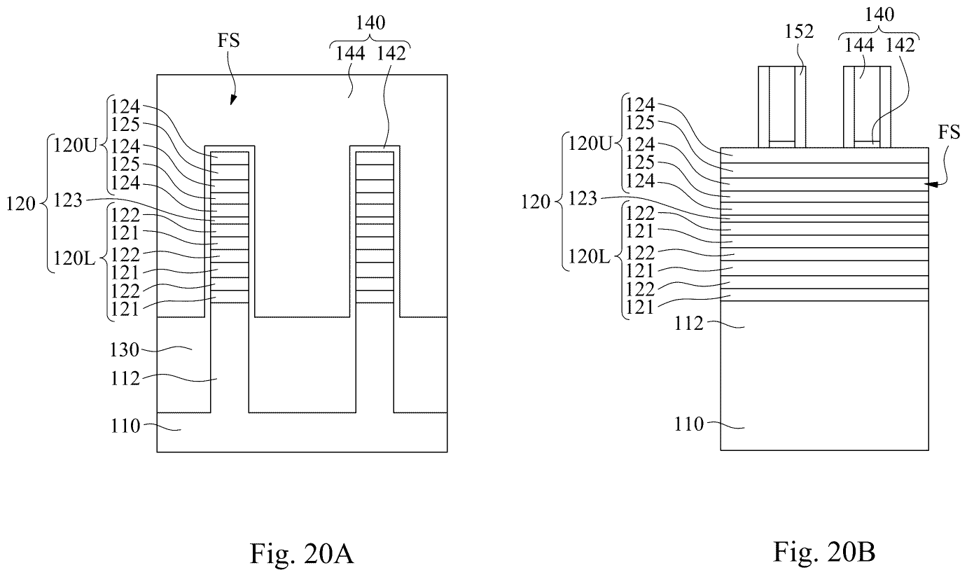

FIGS. 20A-25C illustrate schematic cross-sectional views of intermediate stages in the manufacture of an integrated circuit device in accordance with some embodiments of the present disclosure. Details of the manufacture of the integrated circuit device in FIGS. 20A-25C are similar to the those in FIGS. 2-9C, except that the manufacture of the integrated circuit device in FIGS. 20A-25C is directed to the integrated circuit device including power rivers (e.g., power conductive features 30B and 30T in FIGS. 19A and 19B).

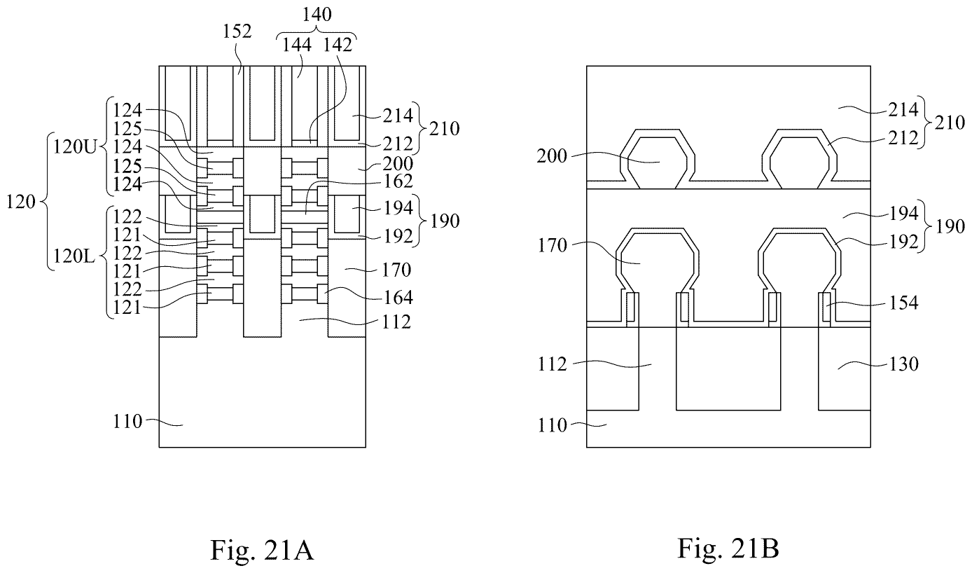

FIGS. 20B, 21A, 24B, and 25B are cross-sectional views of the integrated circuit device (e.g., taken along line X-X in FIGS. 19A and 19B) at various manufacturing stages in accordance with some embodiments. FIGS. 20A, 22A, 23A, 24A, and 25A are cross-sectional views of the integrated circuit device (e.g., taken along line Y1-Y1 in FIGS. 19A and 19B) at various manufacturing stages in accordance with some embodiments. FIGS. 21B, 22B, 23B, and 25C are cross-sectional views of the integrated circuit device (e.g., taken along line Y2-Y2 in FIGS. 19A and 19B) at various manufacturing stages in accordance with some embodiments. It is understood that additional steps may be provided before, during, and after the steps shown in FIGS. 20A-25C, and some of the steps described below can be replaced or eliminated for additional embodiments of the method. The order of the operations/processes may be interchangeable.

Reference is made to FIGS. 20A and 20B. A stack 120 including a lower epitaxial stack 120L, a middle layer 123, and an upper epitaxial stack 120U are formed over a substrate 110. The epitaxial stack 120L includes sacrificial layers 121 and channel layers 122 alternately arranged over the substrate 110. The epitaxial stack 120U includes channel layers 124 and sacrificial layers 125 alternately arranged over the middle layer 123. The stack 120 and the substrate 110 are patterned into semiconductor fins FS, and an isolation structure 130 is formed in a trench FT around the fins FS. Dummy gate structures 140 and the gate spacers 152 are formed on the epitaxial stack 120. Details of these steps are illustrated with respect to FIG. 2-4B, and thereto not repeated herein.

Reference is made to FIGS. 21A and 21B. Exposed portions of the semiconductor fins FS that extend laterally beyond the gate spacers 152 are etched. Inner spacers 164 may be formed on opposite end surfaces of the sacrificial layers 121 and 125. The middle layer 123 (referring to FIGS. 20A and 20B) is replaced with a dielectric layer 162. The source/drain epitaxial structures 170, the dielectric structures 190, the source/drain epitaxial structures 200, and the dielectric structures 210 are formed. Details of these steps are illustrated with respect to FIG. 5A-7B, and thereto not repeated herein.

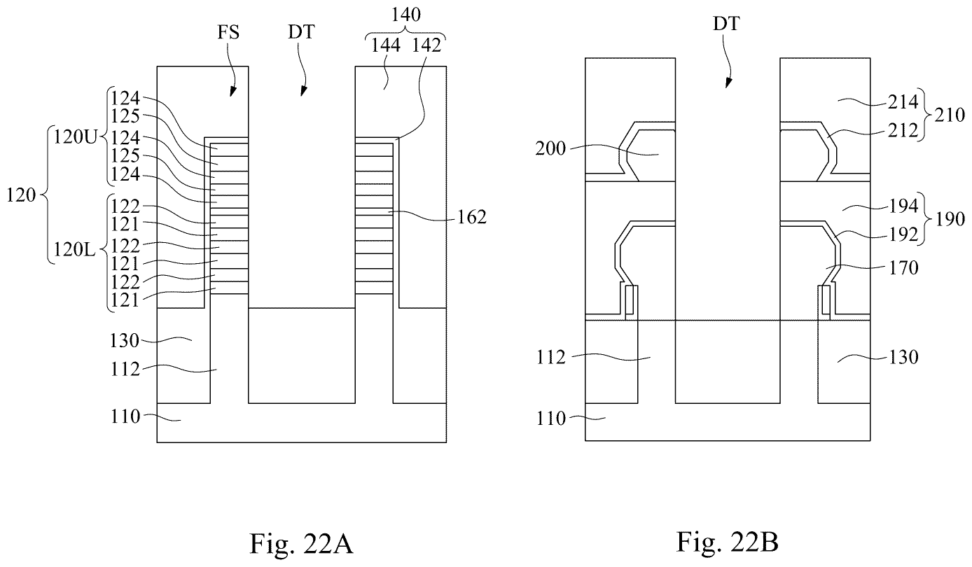

Reference is made to FIGS. 22A and 22B. A trench DT is etched in the dummy gate structure 140 and the dielectric structures 190 and 210. The trench DT may expose sidewalls of the source/drain epitaxial structures 170 and the source/drain epitaxial structures 200.

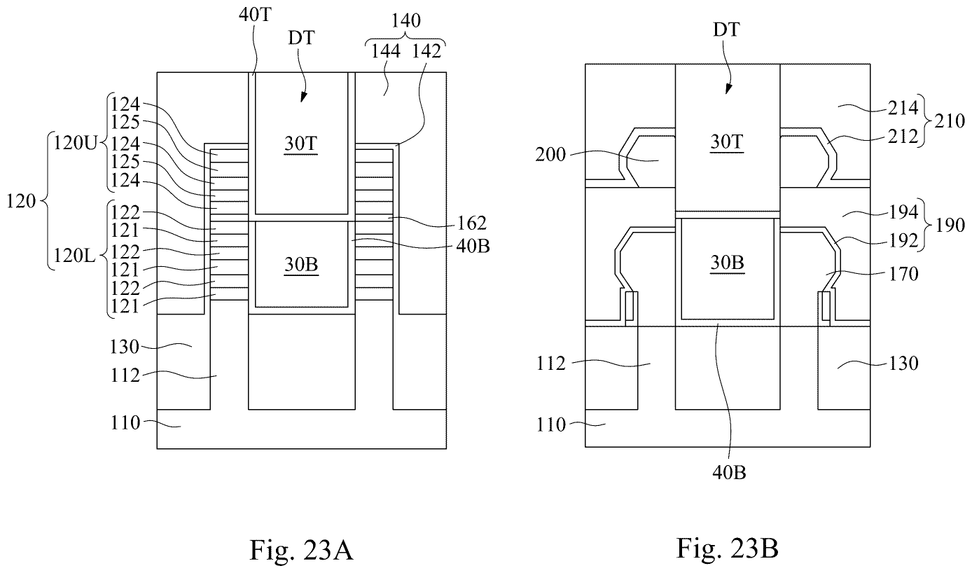

Reference is made to FIGS. 23A and 23B. An isolation layer 40B is conformally deposited into the trench DT, and the deposited isolation layer 40B is recessed to expose the sidewalls of the source/drain epitaxial structures 200. The isolation layer 40B is optionally patterned. In the present embodiments, as shown in FIG. 19B, the isolation layer 40B is free of being patterned and covers the sidewalls of all of the source/drain epitaxial structures 170. In some other embodiments, the isolation layer 40B is patterned to expose the sidewalls of some of the source/drain epitaxial structures 170, and covers the sidewalls of the others of the source/drain epitaxial structures 170. By depositing conductive materials over the isolation layer 40B and etching back the conductive materials, a lower power conductive feature 30B is formed over the isolation layer 40B. The isolation layer 40B may space the sidewalls of the source/drain epitaxial structures 170 from the lower power conductive feature 30B.

An isolation layer 40T is conformally deposited into the trench DT. The isolation layer 40T is optionally patterned. In the present embodiments, as shown in FIG. 19A, the isolation layer 40T is patterned to expose the sidewalls of some of the source/drain epitaxial structures 200, and covers the sidewalls of the others of the source/drain epitaxial structures 200. In some other embodiments, the isolation layer 40T is free of being patterned and covers the sidewalls of all of the source/drain epitaxial structures 200. By depositing conductive materials over the isolation layer 40T and etching back the conductive materials, a power conductive feature 30T is formed over the isolation layer 40T. The power conductive feature 30T may be in contact with the sidewalls of some of the source/drain epitaxial structures 200. The isolation layer 40T may space the sidewalls of the others of the source/drain epitaxial structures 200 from the top power conductive feature 30T.

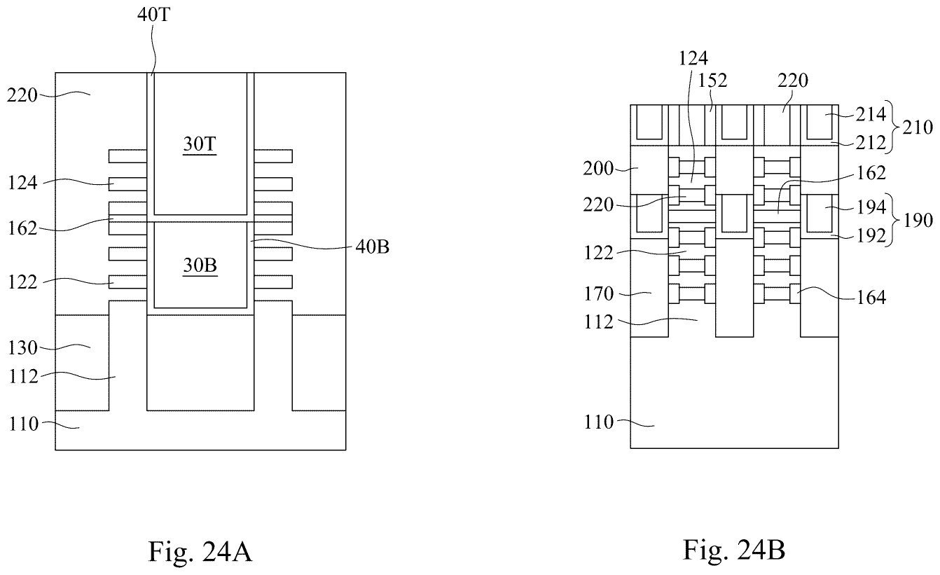

Reference is made to FIGS. 24A and 24B. The dummy gate structure 140 and the sacrificial layer 121 and 125 (referring to FIGS. 23A and 23B) are replaced with a high-k/metal gate structure 220. Details of the replacement process are similar to those illustrated in FIGS. 8A and 8B, and thereto not repeated herein.

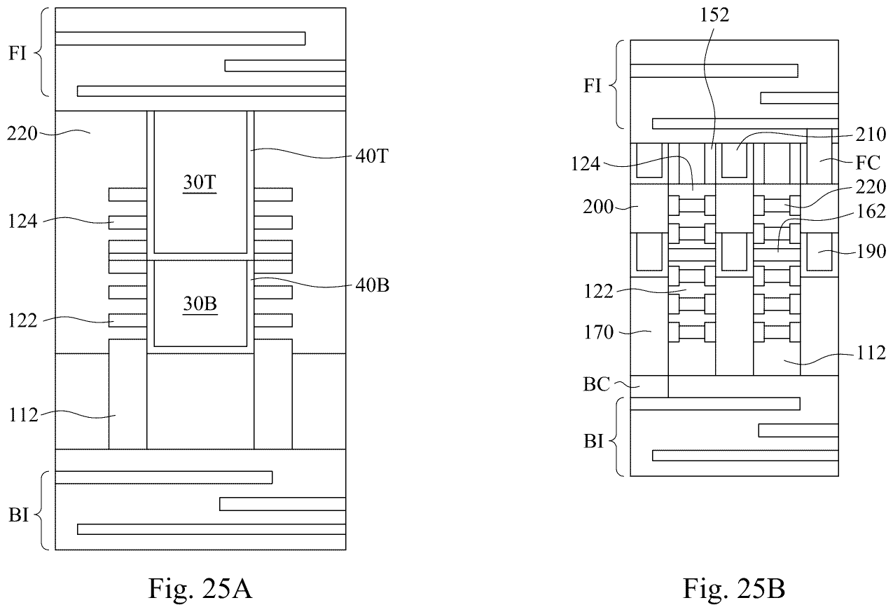

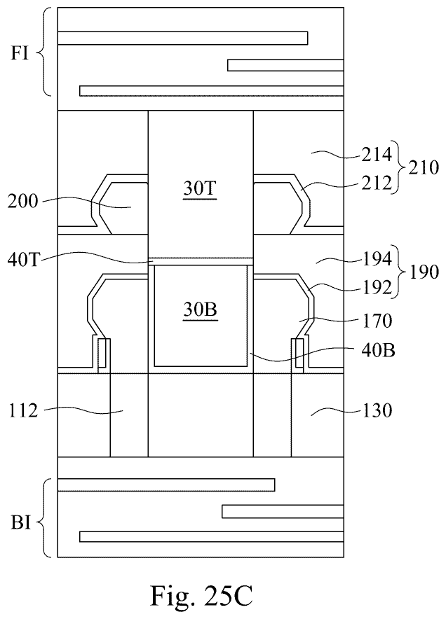

Reference is made to FIGS. 25A-25C. The front-side contact FC, the front-side multilayer interconnection (MLI) structure FI, the back-side contact BC, and the back-side MLI structure BI are formed. Other details of the manufacture of the integrated circuit device are similar to those in FIGS. 2-9C, and thereto not repeated herein.

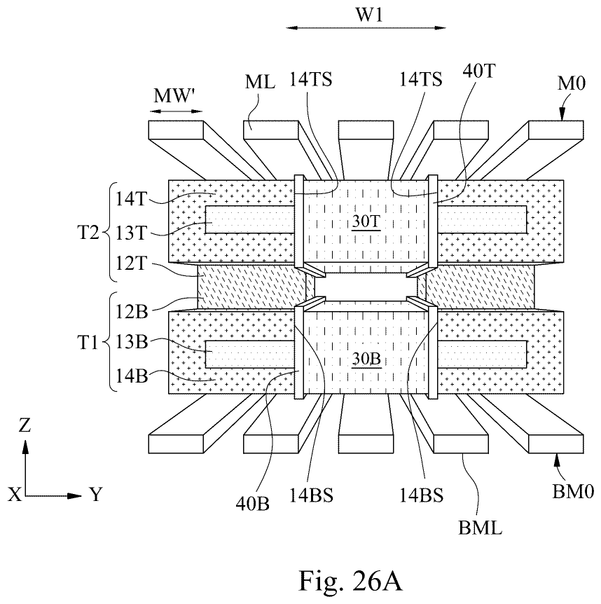

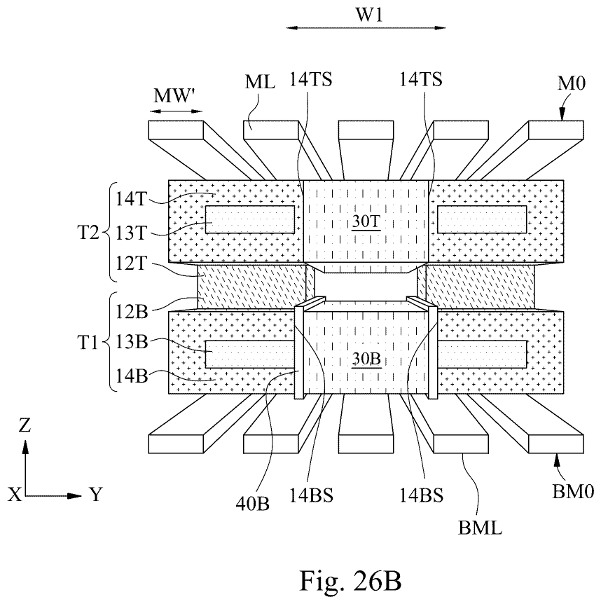

FIGS. 26A and 26B are perspective views of an integrated circuit device in accordance with some embodiments of the present disclosure. Details of the present embodiments are similar to those of FIGS. 19A-19D, except that the width MW of the metal lines ML of the metallization layer M0 is enlarged. For example, in the present embodiments, the ratio between the width W1 of the power conductive features 30T and 30B and the width MW of the metal lines ML of the metallization layer M0 may be in a range from about 1 to about 2.5. Other details of the present embodiments are similar to those of FIGS. 19A-19D, and thereto not repeated herein.

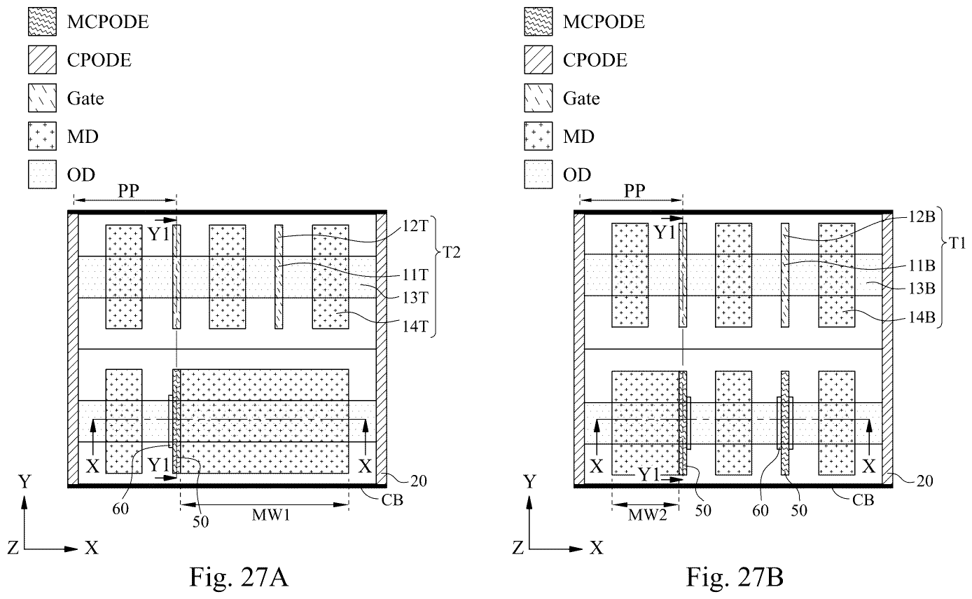

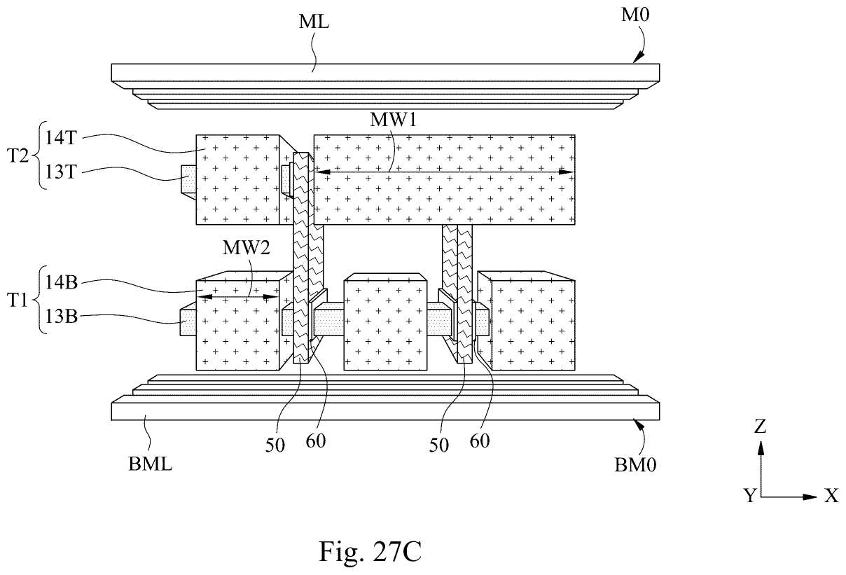

FIGS. 27A and 27B are respectively layout diagrams of upper and lower portions of an integrated circuit device in accordance with some embodiments of the present disclosure. FIG. 27C is a perspective view of an integrated circuit device according to the layout diagrams in FIGS. 27A and 27B. As described previously, the integrated circuit device may include one or plural CFET structures, each of the CFET structures includes a bottom transistor TR1 and a top transistor TR2 vertically stacked over the bottom transistor TR1. In some embodiments, the top gate structure 12T and the bottom gate structure 12B may share a continuous gate structure, such that the top gate structure 12T is electrically connected with the bottom gate structure 12B. In some other embodiments, the top gate structure 12T can be electrically isolated from the bottom gate structure 12B by a MDI (not shown), in which the MDI may separate the top gate structure 12T from the bottom gate structure 12B.

In the layout diagrams of FIGS. 27A and 27B, the active regions, also referred to as oxide-diffusion regions, denoted as “OD” in the context, extend substantially along the direction X. The active region may include one or more channel regions 11T/11B and one or more source/drain regions 13T/13B. The gate structures 12T and 12B, denoted as “Gate”, extend in the direction Y. The gate structures can be polysilicon strips or high-k/metal gate structures. Source/drain conductive structure, denoted as “MD”, surrounds and connects the source/drain region 13T/13B of the transistors TR2/TR1. In the layout diagrams, the cell may include two dielectric gates 20 at the two boundary lines oriented along the direction Y. The dielectric gates 20 may be referred to as continuous polysilicon on oxide diffusion edge (CPODE), denoted as “CPODE.”

The vertical conductive features 50 and the gate structures 12T/12B extend along a same direction Y. In some embodiments, the dielectric gates 20 and the vertical conductive features 50 are spaced apart from each other by the same gate pitch PP along the direction X. The vertical conductive features 50 may be aligned with the gate structures 12T/12B along the direction Y. The vertical conductive features 50 may be disposed at ends of the active layer of the bottom transistor T1 and the top transistor T2. The vertical conductive features 50 are not gates and do not function as gates. Instead, the vertical conductive features 50 are metal features that include one or more metal materials and function as electrically conductive features, in some instances. The vertical conductive features 50 may be denoted as “MCPODE.” The vertical conductive features 50 may be in contact with the source/drain conductive structures 14T and 14B of a pair of stacked top and bottom transistors T2 and T 1. In some embodiments, some of the source/drain conductive structures 14T/14B may be enlarged to connect the vertical conductive features 50. For example, the source/drain conductive structures 14T in contact with the vertical conductive features 50 may have a width MW1 greater than the gate pitch PP, and the source/drain conductive structures 14B in contact with the vertical conductive features 50 may have a width MW2 greater than half the gate pitch PP.

Isolation layers 60 are configured to electrically isolate the vertical conductive features 50 from some of the transistors, and allow the electrical connection between the others of the transistors and the vertical conductive features 50. The isolation layers 60 isolate the vertical conductive features 50 from some of the active regions (OD) (e.g., the channel regions 11T/11B and the source/drain regions 13T/13B) and the source/drain conductive structures 14T/14B of the transistors. And, the vertical conductive feature 50 is in contact with some others of the active regions (OD) (e.g., the channel regions 11T/11B and the source/drain regions 13T/13B) and the source/drain conductive structures 14T/14B of the transistors.

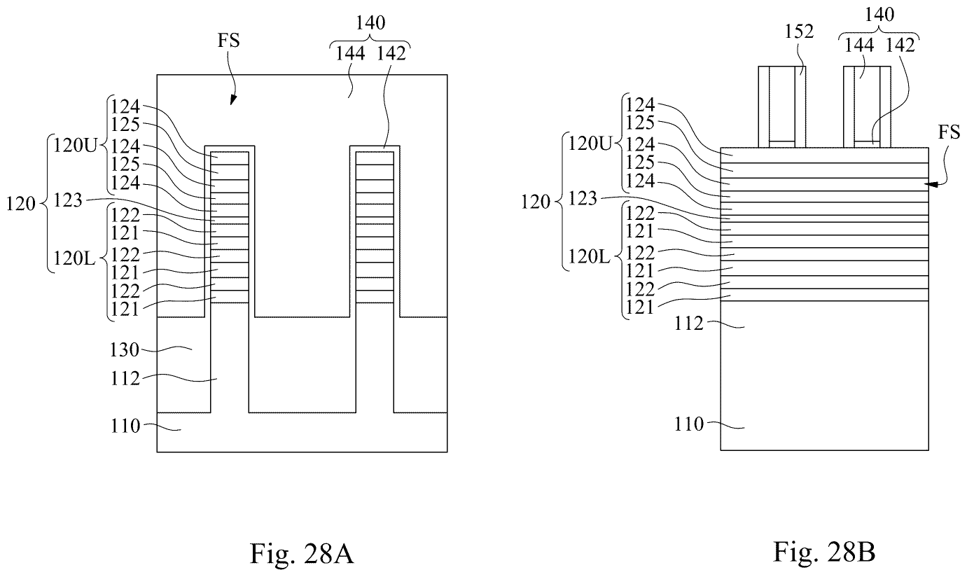

FIGS. 28A-37B illustrate schematic cross-sectional views of intermediate stages in the manufacture of an integrated circuit device in accordance with some embodiments of the present disclosure. Details of the manufacture of the integrated circuit device in FIGS. 28A-37B are similar to the those in FIGS. 2-9C, except that the manufacture of the integrated circuit device in FIGS. 28A-37B is directed to the integrated circuit device including vertical conductive features 50 (e.g., the vertical conductive feature 50 in FIGS. 27A and 27B).

FIGS. 28B, 30-35, 36B, and 37B are cross-sectional views of the integrated circuit device (e.g., taken along line X-X in FIGS. 27A and 27B) at various manufacturing stages in accordance with some embodiments. FIGS. 28A, 29, 36A, and 37A are cross-sectional views of the integrated circuit device (e.g., taken along line Y1-Y1 in FIGS. 27A and 27B) at various manufacturing stages in accordance with some embodiments. It is understood that additional steps may be provided before, during, and after the steps shown in FIGS. 28A-37B, and some of the steps described below can be replaced or eliminated for additional embodiments of the method. The order of the operations/processes may be interchangeable.

Reference is made to FIGS. 28A and 28B. A stack 120 including a lower epitaxial stack 120L, a middle layer 123, and an upper epitaxial stack 120U are formed over a substrate 110. The epitaxial stack 120L includes sacrificial layers 121 and channel layers 122 alternately arranged over the substrate 110. The epitaxial stack 120U includes channel layers 124 and sacrificial layers 125 alternately arranged over the middle layer 123. The stack 120 and the substrate 110 are patterned into semiconductor fins FS, and an isolation structure 130 is formed in a trench FT around the fins FS. Dummy gate structures 140 and the gate spacers 152 are formed on the epitaxial stack 120. Details of these steps are illustrated with respect to FIG. 2-4B, and thereto not repeated herein.

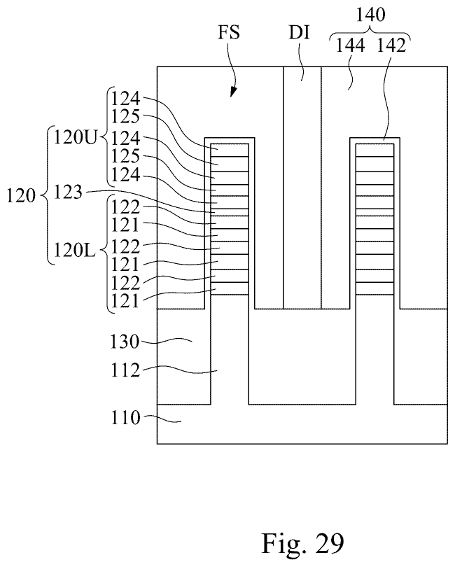

Reference is made to FIG. 29. A dielectric feature DI is formed in the dummy gate structures 140. The dielectric feature DI may cut the dummy gate structures 140 into two separate dummy gate structures. The dielectric feature DI may include suitable dielectric materials, such as silicon oxide, silicon nitride, silicon oxynitride, the like, or the combination thereof. Formation of the dielectric feature DI may include etching a trench in the dummy gate structures 140 and depositing the dielectric materials into the trench, followed by a planarization process.

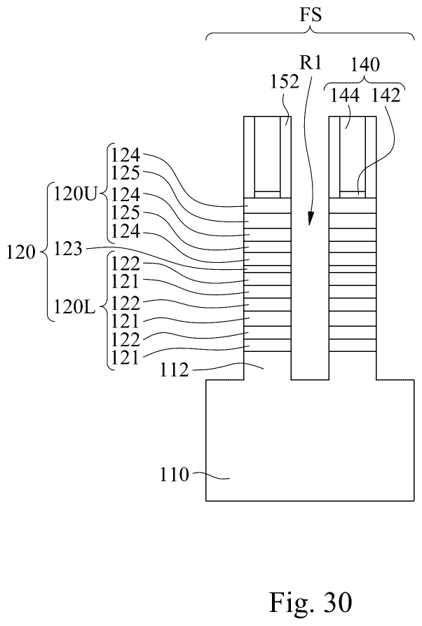

Reference is made to FIG. 30. Exposed portions of the semiconductor fins FS that extend laterally beyond the gate spacers 152 (e.g., in source/drain regions of the fins FS) are etched by using, for example, an anisotropic etching process, resulting in recesses R1 into the semiconductor fins FS and between corresponding dummy gate structures 140.

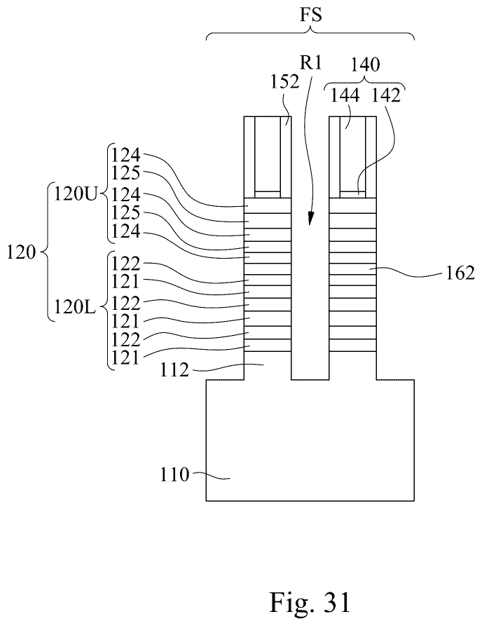

Reference is made to FIG. 31. The middle layer 123 (referring to FIG. 30) is replaced with a dielectric layer 162, which may include a dielectric material, such as silicon nitride, silicon oxide, silicon oxynitride, the like, or the combination thereof.

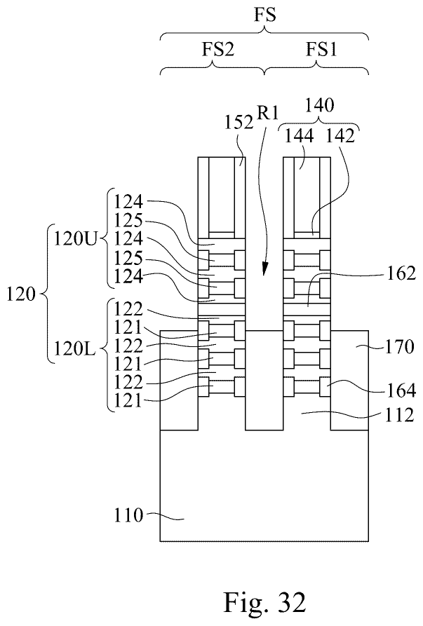

Reference is made to FIG. 32. Source/drain epitaxial structures 170 are formed in the recesses R1. The source/drain epitaxial structures 170 may be formed by performing an epitaxial growth process that provides an epitaxial material on the surfaces of the exposed surfaces of the channel layer 122. Suitable epitaxial processes include CVD deposition techniques, molecular beam epitaxy, and/or other suitable processes. The epitaxial growth process may use gaseous and/or liquid precursors, which interact with the composition of semiconductor materials of the channel layer 122. In some embodiments, one or more etching processes may be performed to lower top surfaces of the source/drain epitaxial structures 170. The resulted source/drain epitaxial structures 170 have a top surface lower than that of the channel layer 124. The etching process may be dry etch, wet etch, or the combination thereof.

Reference is made to FIG. 33. The dummy gate structure 140 in a first portion FS1 of the fins FS and the epitaxial stack 120 therebelow are replaced with the isolation layers 60_1 (referred to as the isolation layers 60 in FIG. 27B) and the vertical conductive features 50_1 (referred to as vertical conductive features 50 in FIG. 27B). The first portion FS1 and the second portion FS2 of the fins FS overlapping two dummy gate structures 140, respectively. The replacement process includes etching processes and depositing processes. The etching processes may remove the dielectric layer 162 and the inner spacers 164 from the first portion FS1 of the fins FS. After the replacement process, top surfaces of the isolation layers 60_1 and the vertical conductive features 50_1 may be lowered to a position below the epitaxial stack 120U by suitable etching process.

In the present embodiments, the isolation layers 60_1 may separate the vertical conductive features 50_1 apart from the source/drain epitaxial structures 170. In some embodiments, the isolation layers 60_1 may be patterned, and the vertical conductive features 50_1 may be in contact with some of the source/drain epitaxial structures 170 and spaced apart from the other of the source/drain epitaxial structures 170 by the patterned isolation layers 60_1.

Reference is made to FIG. 34. In some embodiments, the dielectric structures 190 and the source/drain epitaxial structures 200, and the dielectric structures 210 are formed. Source/drain epitaxial structures 200 are formed in the recesses R1 on opposite sides of the channel layers 124. The source/drain epitaxial structures 200 may be formed by performing an epitaxial growth process that provides an epitaxial material on the exposed surfaces of the channel layers 124. Suitable epitaxial processes include CVD deposition techniques, molecular beam epitaxy, and/or other suitable processes. The epitaxial growth process may use gaseous and/or liquid precursors, which interact with the composition of semiconductor materials of the channel layers 124.

By forming the isolation layers 60_1 and the vertical conductive features 50_1 in the first portion FS1 and lowering the top surfaces of the isolation layers 60_1 and the vertical conductive features 50_1 to the position below the epitaxial stack 120U, the source/drain epitaxial structures 200 can be formed with a width much greater than a width of the source/drain epitaxial structures 170. After the formation of the source/drain epitaxial structures 200, the dielectric structures 210 are formed thereon. The resulted structure is shown in FIG. 35.

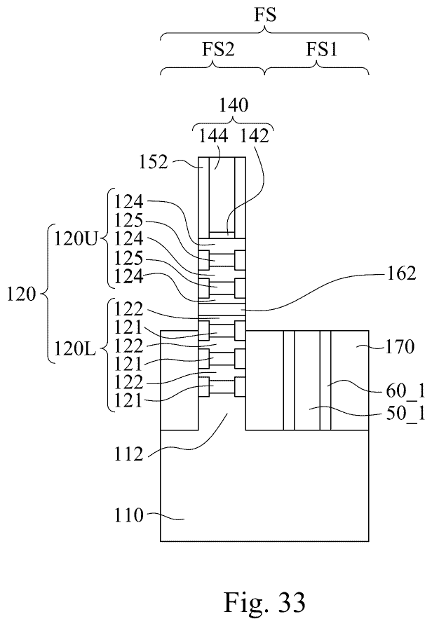

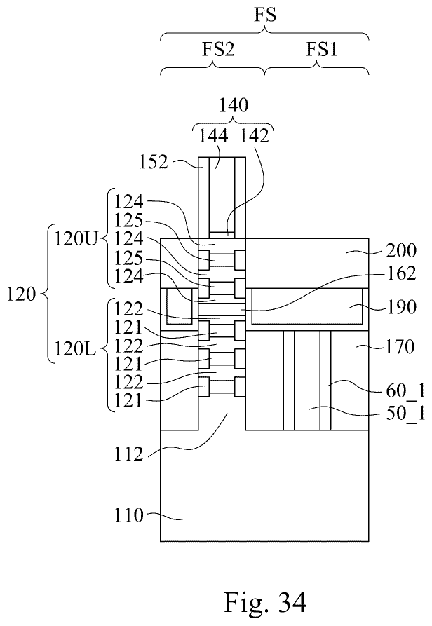

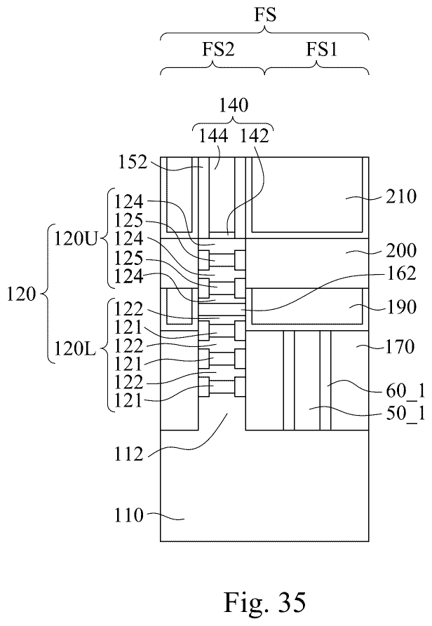

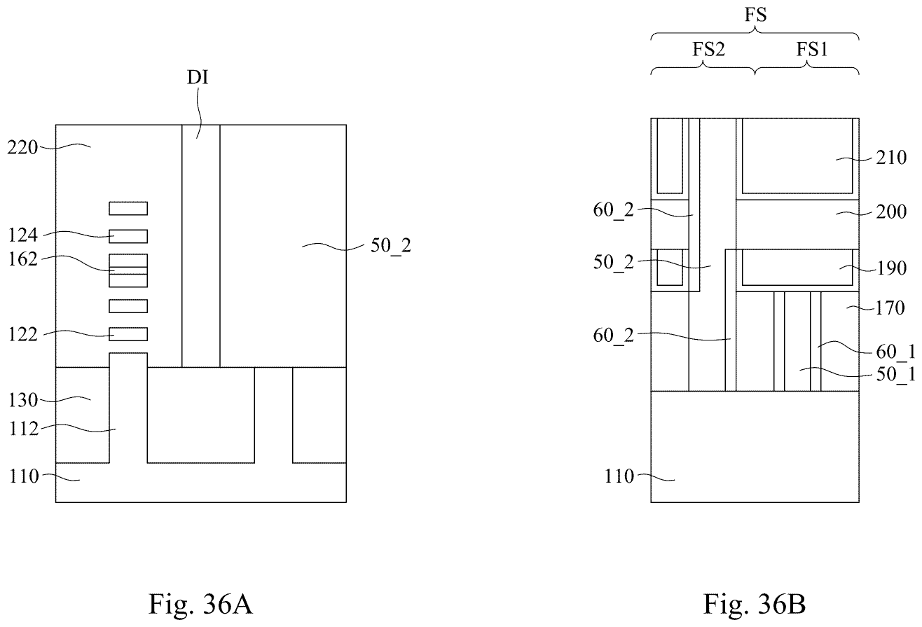

Reference is made to FIGS. 36A and 36B. The dummy gate structure 140 in the second portion FS2 of the fins FS and the epitaxial stack 120 therebelow are replaced with the isolation layers 60_2 (referred to as the isolation layers 60 in FIGS. 27A and 27B) and the vertical conductive features 50_2 (referred to as vertical conductive features 50 in FIGS. 27A and 27B). The replacement process includes etching processes and depositing processes. The etching process may also remove the dielectric layer 162 and the inner spacers 164 from the first portion FS2 of the fins FS.

In the present embodiments, the isolation layers 60_2 may be patterned. For example, the vertical conductive features 50_2 may be in contact with some of the source/drain epitaxial structures 200 and some of the source/drain epitaxial structures 170 and spaced apart from the other of the source/drain epitaxial structures 200 and the other of the source/drain epitaxial structures 170 by the patterned isolation layers 60_2.

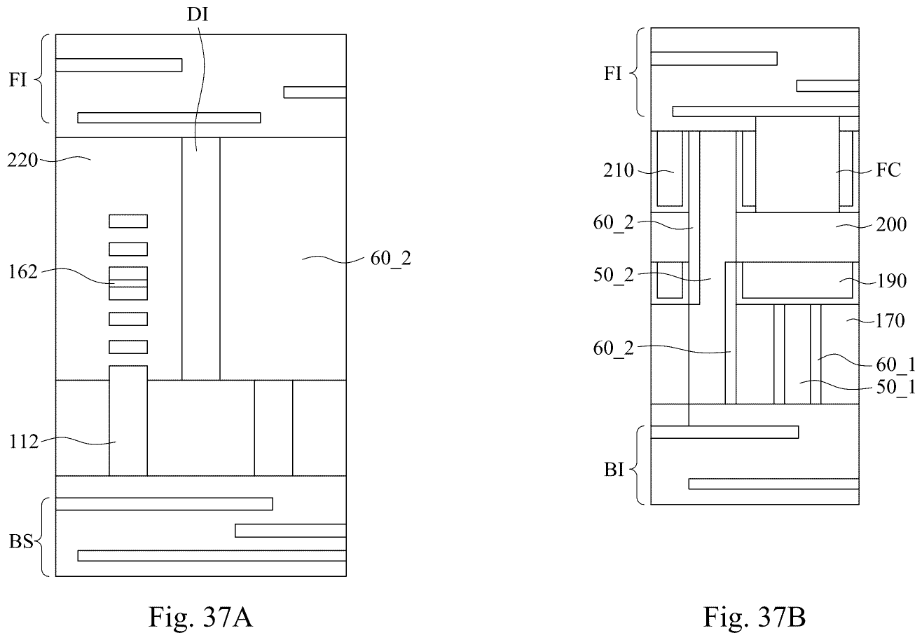

Reference is made to FIGS. 37A and 37B. The front-side contact FC, the front-side multilayer interconnection (MLI) structure FI, the back-side contact BC, and the back-side MLI structure BI are formed. Other details of the manufacture of the integrated circuit device are similar to those in FIGS. 2-9C, and thereto not repeated herein.

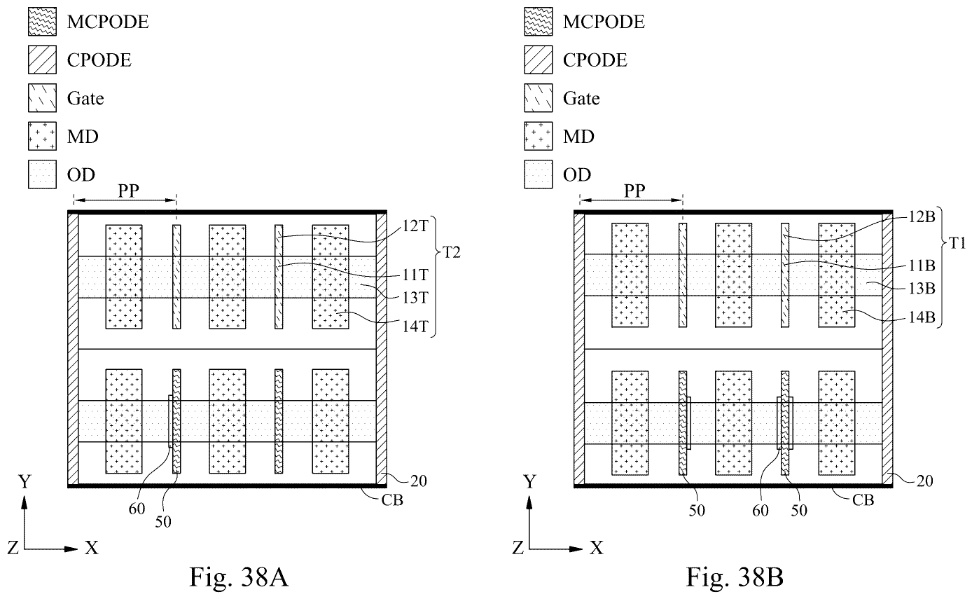

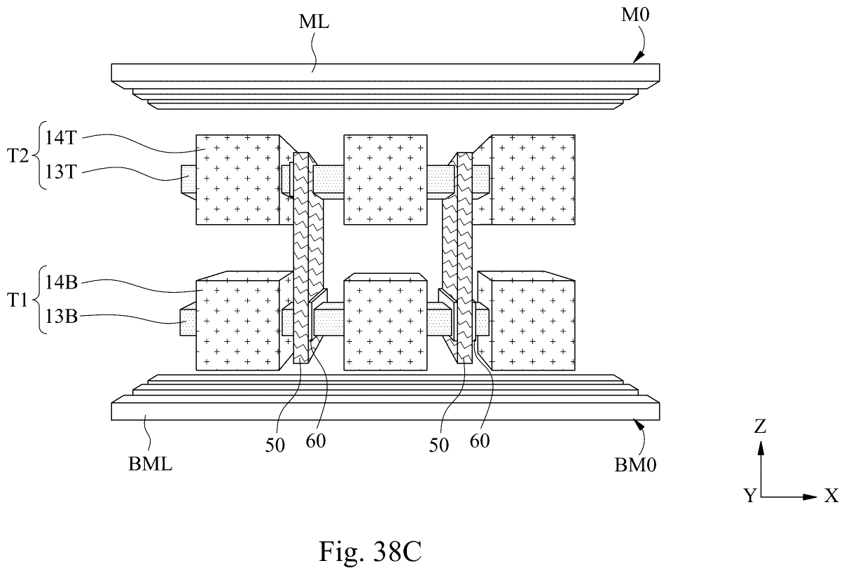

FIGS. 38A and 38B are respectively layout diagrams of upper and lower portions of an integrated circuit device in accordance with some embodiments of the present disclosure. FIG. 38C is a perspective view of an integrated circuit device according to the layout diagrams in FIGS. 38A and 38B. Details of the present embodiments are similar to those of the embodiments of FIGS. 27A-27C, except that the vertical conductive features 50 are in contact with the source/drain regions 13T and 13B, and the source/drain conductive structures 14T/14B adjoining the source/drain regions 13T and 13B may be spaced apart from the vertical conductive features 50. For example, the source/drain conductive structures 14T/14B on opposite sides of the vertical conductive features 50 have the same width. Other details of the present embodiments are similar to those illustrated in the embodiments of FIGS. 27A-27C, and thereto not repeated herein.

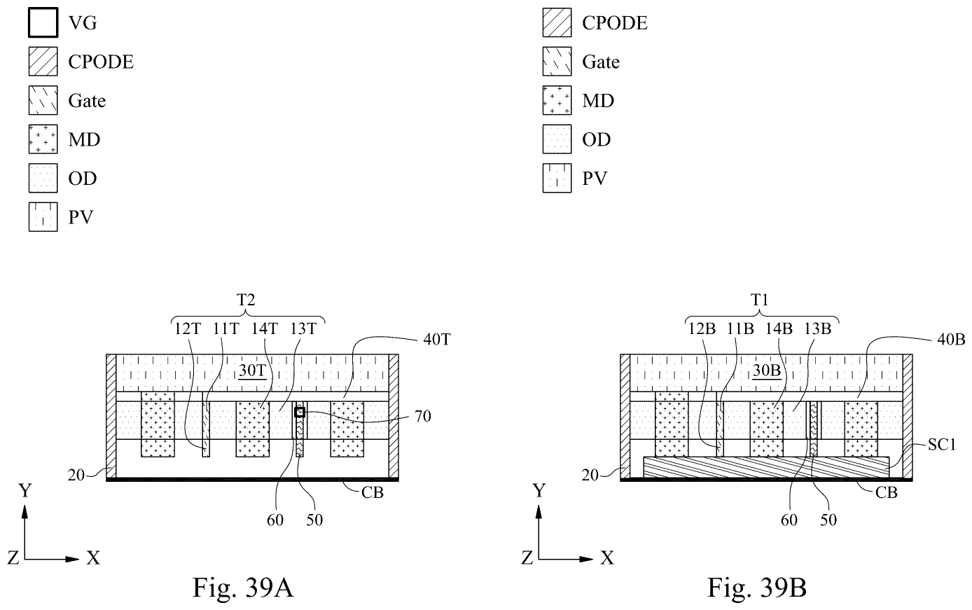

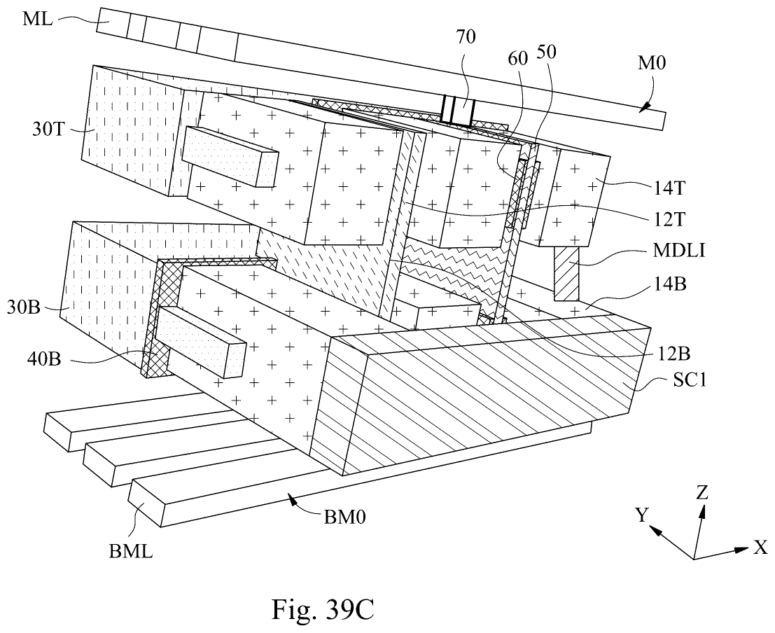

FIGS. 39A and 39B are respectively layout diagrams of upper and lower portions of an integrated circuit device in accordance with some embodiments of the present disclosure. FIG. 39C is a perspective view of an integrated circuit device according to the layout diagrams in FIGS. 39A and 39B. As described previously, the integrated circuit device may include one or plural CFET structures, each of the CFET structures includes a bottom transistor TR1 and a top transistor TR2 vertically stacked over the bottom transistor TR1. In some embodiments, the top gate structure 12T and the bottom gate structure 12B may share a continuous gate structure, such that the top gate structure 12T is electrically connected with the bottom gate structure 12B. In some other embodiments, the top gate structure 12T can be electrically isolated from the bottom gate structure 12B by dielectric bonding materials (not shown), in which a dielectric bonding layer may separate the top gate structure 12T from the bottom gate structure 12B.

In the present embodiments, the integrated circuit device includes the side connection structures SC1, the power conductive features 30B and 30T, the isolation layers 40T and 40B, the vertical conductive features 50, and the isolation layers 60. As aforementioned, the isolation layers 40T and 40B are configured to electrically isolate the power conductive feature 30T and 30B from some of the transistors, and allow the electrical connection between the others of the transistors and the power conductive feature 30T and 30B. And, the isolation layers 60 are configured to electrically isolate the vertical conductive features 50 from some of the transistors, and allow the electrical connection between the others of the transistors and the vertical conductive features 50.

In some embodiments, a contact plug 72, denoted as “VG” in the context, may land on the vertical conductive features 50. The contact plug 72 may connect the vertical conductive features 50 to the metal lines ML of the metallization layer M0. The contact plug 72 may include suitable metal, such as tungsten.

A method for forming the integrated circuit device in FIGS. 39A-39C includes forming bottom transistors TR1 and top transistors TR2 vertically stacked over the bottom transistor TR1. Formation of the bottom transistor TR1 and the top transistors TR2 may include forming semiconductor channel regions 11B, forming a semiconductor channel regions 11T above the semiconductor channel regions 11B, forming the gate structures 12B and 12T around the semiconductor channel regions 11B and 11T, forming the source/drain regions 13B adjoining the semiconductor channel regions 11B, forming the source/drain regions 13T adjoining the semiconductor channel regions 11T, forming source/drain conductive structures 14B surrounding the source/drain regions 13B, and forming source/drain conductive structures 14T surrounding the source/drain regions 13T.

Before or after the formation of the bottom transistor TR1 and the top transistor TR2, side connection structures SC1 (or the side connection structures SC2-SC7 described previously) may be formed in the isolation structure 90 between the active region to electrically connect two of the bottom transistors TR1 and the top transistors TR2.

Before or after the formation of the bottom transistor TR1 and the top transistor TR2, power conductive features 30B and 30T may be formed in the isolation structure 90 between the active region to provide power to the bottom transistors TR1 to the top transistors TR2.

Before or after the formation of the bottom transistor TR1 and the top transistor TR2, a vertical conductive feature 50 is formed at ends of the active regions of the bottom transistor TR1 and the top transistor TR2, thereby electrically connecting the bottom transistor TR1 to the top transistor TR2. And, isolation layers 60 are formed to spacing the vertical conductive feature 50 from some of the bottom transistor TR1 and the top transistor TR2. Other details of the present disclosure are similar to those illustrated above, and thereto not repeated herein.

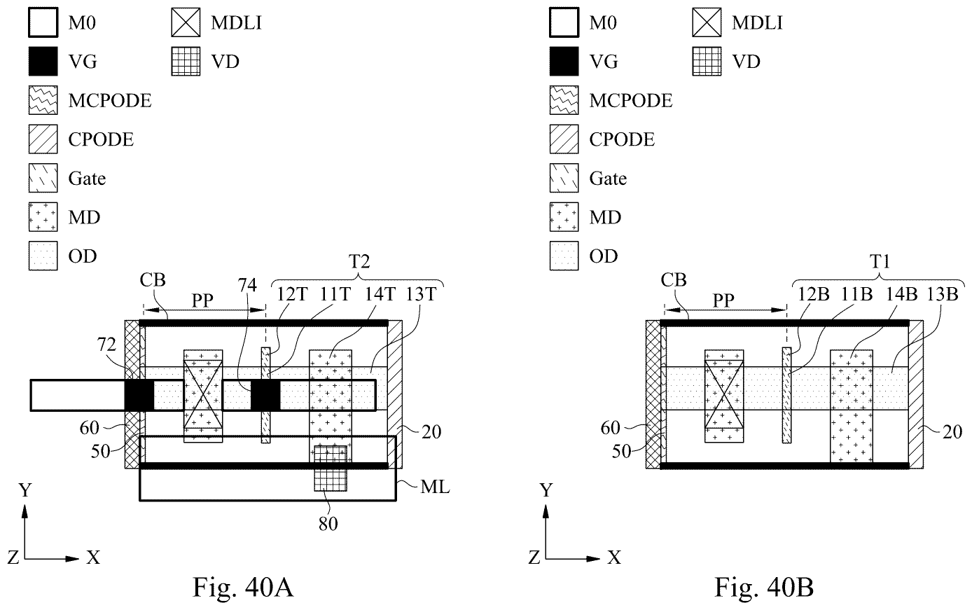

FIGS. 40A and 40B are respectively layout diagrams of upper and lower portions of an integrated circuit device in accordance with some embodiments of the present disclosure. The integrated circuit device is illustrated as an inverter cell surrounded by a cell boundary indicated by bolded lines CB. The inverter cell may have a top transistor T2 stacked over a bottom transistor T1. In some embodiments, the top transistor T2 is a NMOS device, and the bottom transistor T1 is a PMOS device. In some other embodiments, the top transistor T2 is a PMOS device, and the bottom transistor T1 is an NMOS device.

The top transistor T2 includes at least one top semiconductor channel region 11T, a top gate structure 12T, top source/drain regions 13T, and top source/drain conductive structures 14T. The bottom transistor T1 includes at least one bottom semiconductor channel region 11B, a bottom gate structure 12B, bottom source/drain regions 13B, and bottom source/drain conductive structures 14B. In the present embodiments, the channel region 11B, the bottom gate structure 12B, the bottom source/drain regions 13B, and the bottom source/drain conductive structures 14B of the bottom transistor T1 may have a same layout configuration as that of the top transistor T2.

In the layout diagrams, the cell may include a dielectric gate 20 and a vertical conductive feature 50 at the two boundary lines oriented along the direction Y. The dielectric gate 20, the vertical conductive feature 50, and the gate structures 12T/12B extend along a same direction Y, and every adjacent two of the dielectric gate 20, vertical conductive feature 50, and the gate structures 12T/12B are spaced apart from each other by a same gate pitch PP along the direction X. The dielectric gate 20 and the vertical conductive feature 50 are not a gate and does not function as a gate. Instead, the dielectric gate 20 is a dielectric feature that includes one or more dielectric materials and functions as an isolation feature, in some instances. The vertical conductive feature 50 is a metal feature that includes one or more metal materials and functions as an electrically conductive feature, in some instances. The dielectric gate 20 may be referred to as continuous polysilicon on oxide diffusion edge (CPODE), denoted as “CPODE.” The vertical conductive features 50 may be denoted as “MCPODE.”

In the present embodiments, for forming the inverter cell, the top gate structure 12T of the top transistor T2 and the bottom gate structure 12B of the bottom transistor T1 may share a continuous gate structure, such that the top gate structure 12T of the top transistor T2 is electrically connected with the bottom gate structure 12B of the bottom transistor T1. And, the vertical conductive feature 50 may have opposite first and second sides, in which the first side of the vertical conductive feature 50 is in contact with the top source/drain region 13T of the top transistor T2 and the bottom source/drain region 13B of the bottom transistor T1, and a second side of the vertical conductive feature 50 is in contact with the isolation layer 60. The isolation layer 60 may space the inverter cell from other cells. A contact plug 72 may connect the vertical conductive feature 50 to a first one of the metal lines ML of the metallization layer M0, and the contact plug 74 may connect the top gate structure 12T to a second one of the metal lines ML of the metallization layer M0. The contact plug 72 and 74 are denoted as “VG” in the context. The contact plug 72 and 74 may serve as output node and input node of the inverter cell, respectively.

Source/drain conductive feature 80, denoted as “VD” in the context, may land on one of the top source/drain conductive structures 14T and connect the one of the top source/drain conductive structures 14T to a third one of the metal lines ML of the metallization layer M0. Thus, a power connection is established between the metallization layer M0 and the inverter cell. The feature “MDLI” may establish an electrical connection between the top source/drain region 13T of the top transistor T2 and the bottom source/drain region 13B of the bottom transistor T1 (and/or the top source/drain conductive structure 14T of the top transistor T 2 and the bottom source/drain conductive structure 14B of the bottom transistor T1). The feature “MDLI” may be a conductive feature (e.g., metal feature) located between the top source/drain region 13T and the bottom source/drain region 13B (and/or the top source/drain conductive structure 14T and the bottom source/drain conductive structure 14B). The feature “MDLI” may be referred to as a source terminal/drain terminal connection or interconnect. Other details of the present embodiments are similar to those illustrated above, and thereto not repeated herein.

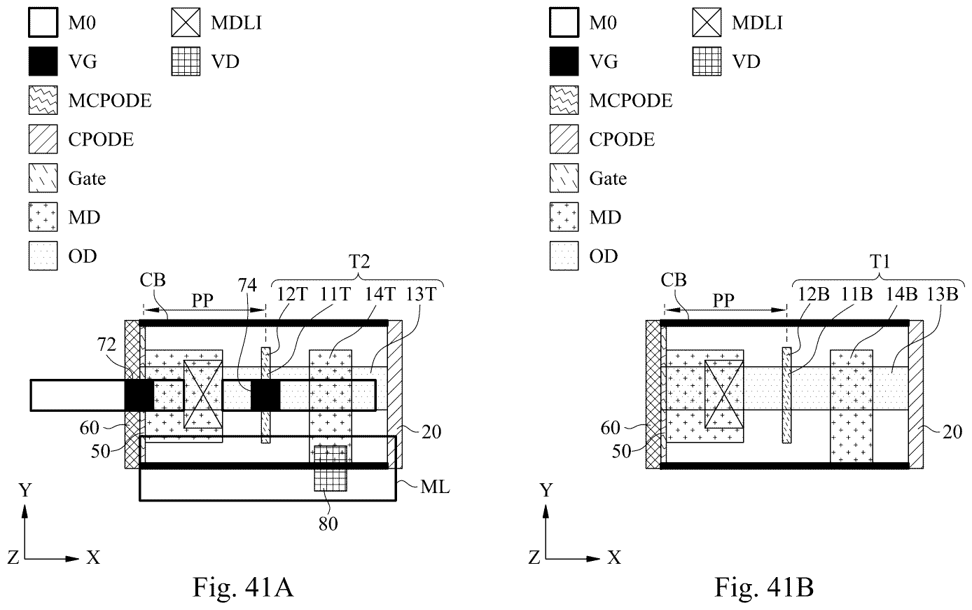

FIGS. 41A and 41B are respectively layout diagrams of upper and lower portions of an integrated circuit device in accordance with some embodiments of the present disclosure. Details of the present embodiments are similar to those of FIGS. 40A and 40B, except that the widths of the source/drain conductive structures 14T and 14B are enlarged to connect the vertical conductive feature 50. For example, the vertical conductive feature 50 may have opposite first and second sides, in which the first side of the vertical conductive feature 50 is in contact with the top source/drain conductive structure 14T of the top transistor T2 and the bottom source/drain conductive structure 14B of the bottom transistor T1, and a second side of the vertical conductive feature 50 is in contact with the isolation layer 60. Other details of the present embodiments are similar to those of the embodiments of FIGS. 40A and 40B, and thereto not repeated herein.

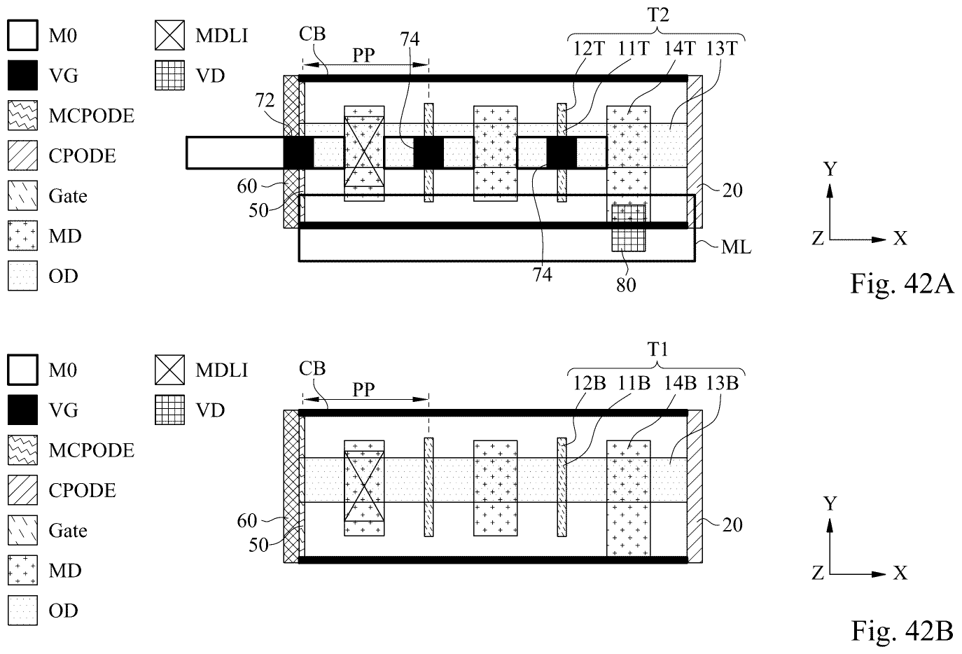

FIGS. 42A and 42B are respectively layout diagrams of upper and lower portions of an integrated circuit device in accordance with some embodiments of the present disclosure. The integrated circuit device is illustrated as a NAND cell surrounded by a cell boundary indicated by bolded lines CB. The NAND cell may have two top transistors T2 respectively stacked over two bottom transistors T1. In some embodiments, the top transistors T2 are NMOS devices, and the bottom transistors T1 are PMOS devices. In some other embodiments, the top transistors T2 are PMOS devices, and the bottom transistors T1 are NMOS devices.

The top transistor T2 includes at least one top semiconductor channel region 11T, a top gate structure 12T, top source/drain regions 13T, and top source/drain conductive structures 14T. The bottom transistor T1 includes at least one bottom semiconductor channel region 11B, a bottom gate structure 12B, bottom source/drain regions 13B, and bottom source/drain conductive structures 14B. In the present embodiments, the channel region 11B, the bottom gate structure 12B, the bottom source/drain regions 13B, and the bottom source/drain conductive structures 14B of the bottom transistor T1 may have a same layout configuration as that of the top transistor T2.

In the layout diagrams, the cell may include a dielectric gate 20 and a vertical conductive feature 50 at the two boundary lines oriented along the direction Y. The dielectric gate 20, the vertical conductive feature 50, and the gate structures 12T/12B extend along a same direction Y, and every adjacent two of the dielectric gate 20, vertical conductive feature 50, and the gate structures 12T/12B are spaced apart from each other by a same gate pitch PP along the direction X. The dielectric gate 20 and the vertical conductive feature 50 are not a gate and does not function as a gate. Instead, the dielectric gate 20 is a dielectric feature that includes one or more dielectric materials and functions as an isolation feature, in some instances. The vertical conductive feature 50 is a metal feature that includes one or more metal materials and functions as an electrically conductive feature, in some instances. The dielectric gate 20 may be referred to as continuous polysilicon on oxide diffusion edge (CPODE), denoted as “CPODE.” The vertical conductive features 50 may be denoted as “MCPODE.”

In the present embodiments, for forming the NAND cell, the bottom gate structure 12B of the bottom transistor and the top gate structure 12T of the top transistor T2 T1 stacked thereon may share a continuous gate structure, such that the bottom gate structure 12B of the bottom transistor is electrically connected with the top gate structure 12T of the top transistor T2 stacked thereon. And, the vertical conductive feature 50 may have opposite first and second sides, in which the first side of the vertical conductive feature 50 is in contact with the top source/drain region 13T of the top transistor T2 and the bottom source/drain region 13B of the bottom transistor T1, and a second side of the vertical conductive feature 50 is in contact with the isolation layer 60. The isolation layer 60 may space the inverter cell from other cells. A contact plug 72 may connect the vertical conductive feature 50 to a first one of the metal lines ML of the metallization layer M0, and two contact plugs 74 may respectively connect the two top gate structure 12T to a second one and a third one of the metal lines ML of the metallization layer M0. The contact plug 72 and 74 are denoted as “VG” in the context. The contact plug 72 and 74 may serve as output node and input nodes of the inverter cell, respectively.

Source/drain conductive feature 80, denoted as “VD” in the context, may land on one of the top source/drain conductive structures 14T and connect the one of the top source/drain conductive structures 14T to a third one of the metal lines ML of the metallization layer M0. Thus, a power connection is established between the metallization layer M0 and the NAND cell. The feature “MDLI” may establish an electrical connection between the top source/drain region 13T of the top transistor T2 and the bottom source/drain region 13B of the bottom transistor T1 (and/or the top source/drain conductive structure 14T of the top transistor T2 and the bottom source/drain conductive structure 14B of the bottom transistor T1). Other details of the present embodiments are similar to those illustrated above, and thereto not repeated herein.

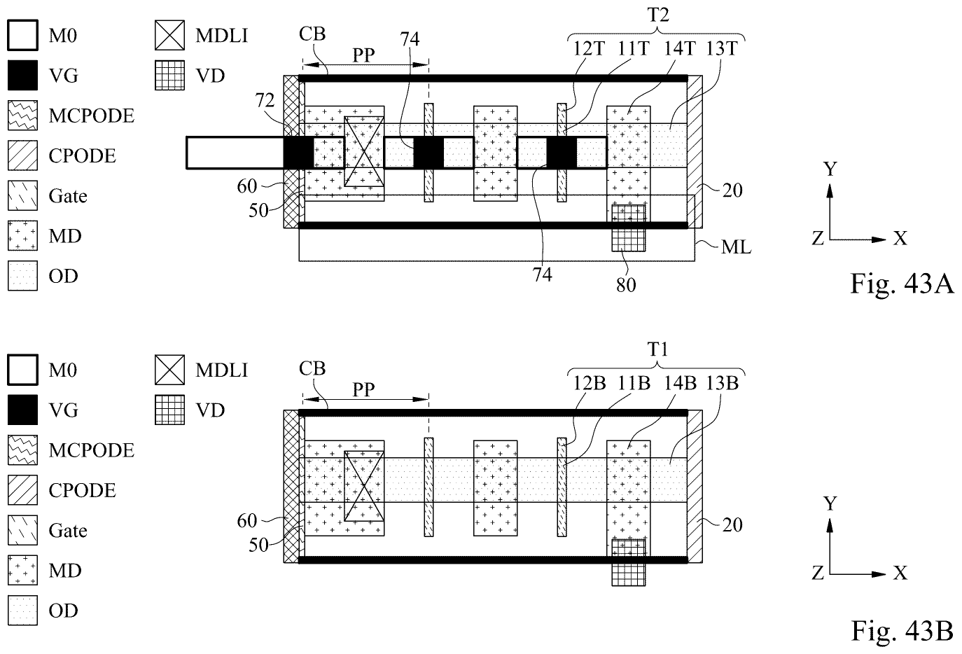

FIGS. 43A and 43B are respectively layout diagrams of upper and lower portions of an integrated circuit device in accordance with some embodiments of the present disclosure. Details of the present embodiments are similar to those of FIGS. 42A and 42B, except that the widths of the source/drain conductive structures 14T and 14B are enlarged to connect the vertical conductive feature 50. For example, the vertical conductive feature 50 may have opposite first and second sides, in which the first side of the vertical conductive feature 50 is in contact with the top source/drain conductive structure 14T of the top transistor T2 and the bottom source/drain conductive structure 14B of the bottom transistor T1, and a second side of the vertical conductive feature 50 is in contact with the isolation layer 60. Other details of the present embodiments are similar to those of the embodiments of FIGS. 42A and 42B, and thereto not repeated herein.

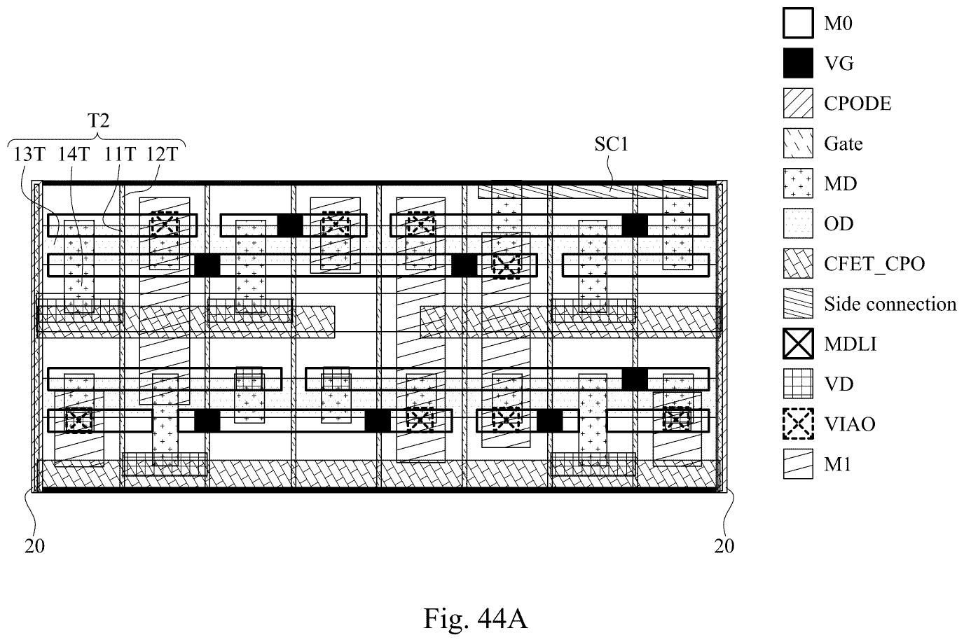

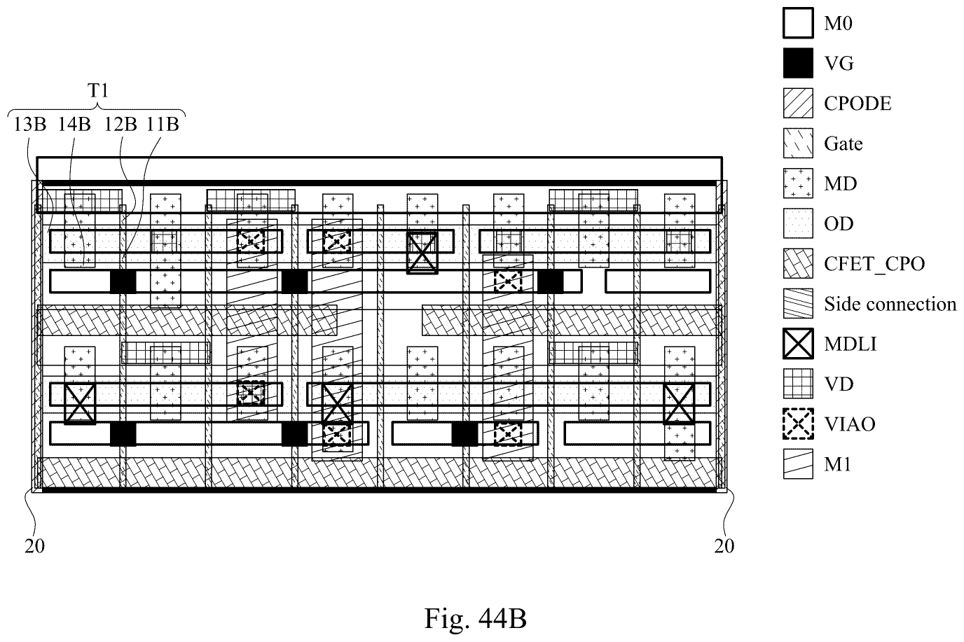

FIGS. 44A and 44B are respectively layout diagrams of upper and lower portions of an integrated circuit device including a full adder in accordance with some embodiments of the present disclosure. The full adder may have plural top transistors T2 respectively stacked over plural bottom transistors T1. In some embodiments, the top transistors T2 are NMOS devices, and the bottom transistors T1 are PMOS devices.

In the layout diagrams, two dielectric gate 20 are at the two boundary lines oriented along the direction Y. A side connection structure SC1, denoted as “Side connection”, is in contact with a lateral side 14TS of one of the source/drain conductive structures 14T and a lateral side 14TS of another one of the source/drain conductive structures 14T, thereby establishing an electrical connection between the two source/drain conductive structures 14T of the bottom transistors T 1. The side connection structure SC1 may extend substantially along the direction the same as that of the active regions, such as the direction X. And, the side connection structure SC1 may include a suitable conductive material, such as doped semiconductor, metal, and/or metal silicide. Other details of the present embodiments are similar to those of the embodiments of FIGS. 42A and 42B, and thereto not repeated herein.

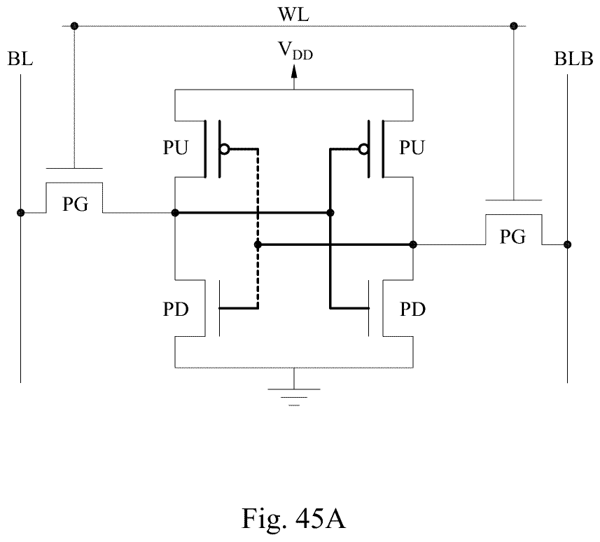

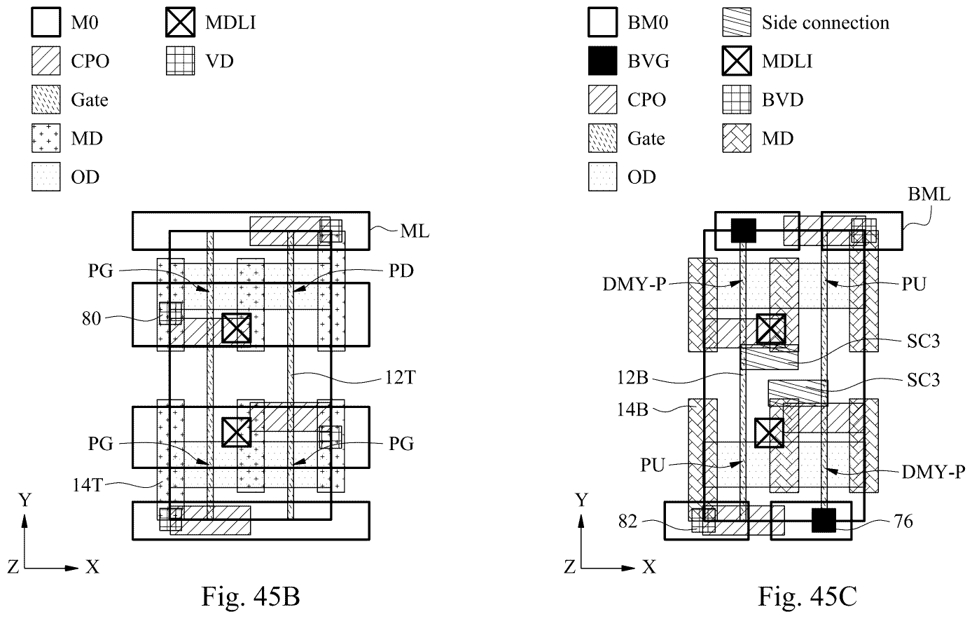

FIG. 45A is a circuit diagram of a SRAM cell in accordance with some embodiments of the present disclosure. The SRAM cell M includes pull-up transistors PU, which are p-type Metal-Oxide-Semiconductor (PMOS) transistors, and pull-down transistors PD and pass-gate transistors PG, which are n-type Metal-Oxide-Semiconductor (NMOS) transistors. The gates of pass-gate transistors PG are controlled by a word line WL that determines whether the SRAM cell is selected or not. A latch formed of pull-up transistors PU and pull-down transistors PD stores a bit, wherein the complementary values of the bit are stored in storage data nodes. The stored bit can be written into, or read from, SRAM cell through complementary bit lines including bit line BL and bit bar line BLB. SRAM cell is powered through a positive power supply node VDD that has a positive power supply voltage. SRAM cell is also connected to a power supply voltage node, which may be an electrical ground. The transistors PU and PD at left side form a first inverter. The transistors PU and PD at right side form a second inverter. The first and second inverters are cross-latched. For example, the input of the first inverter (e.g., gates of the transistors PU and PD) is connected to the output of the second inverter (e.g., drains of the transistors PU and PD), and the output of the first inverter (e.g., drains of the transistors PU and PD) is connected to the input of the second inverter (e.g., gates of the transistors PU and PD). The input of the first inverter is also connected to the transistor PG. The output of the first inverter is also connected to the transistor PG.

The sources of pull-up transistors PU are connected to positive power supply node VDD. The sources of pull-down transistors PD are connected to the power supply voltage node, which may be an electrical ground. The gates of transistors PU and PD of the first inverter are connected to the drains of transistors PU and PD of the second inverter, which form a connection node that is referred to as storage data node. The gates of transistors PU and PD of the second inverter are connected to the drains of transistors PU and PD of the first inverter, which connection node is referred to as storage data node. A source/drain region of pass-gate transistor PG is connected to bit line BL. A source/drain region of pass-gate transistor PG is connected to bit bar line BLB.

FIGS. 45B and 45C are respectively layout diagrams of upper and lower portions of an integrated circuit device including the SRAM cell shown in FIG. 45A. The SRAM cell M may include CFET structures. For example, the SRAM cell may have plural top transistors PD and PG, respectively stacked over plural bottom transistors PU and DMY-P. In some embodiments, the top transistors PD and PG are NMOS devices, and the bottom transistors PU and DMY-P are PMOS devices. The transistors DMY-P are inactive and may be electrically isolated from that of the transistors PD, PG, and PU.

In FIG. 45B, backside contact plugs 76, denoted as “BVG” in the context, may land on backsides of the gate structures 12B. The backside contact plugs 76 may connect the gate structures 12B to the metal lines BML of the metallization layer BM0. The backside source/drain conductive features 82 may include suitable metal, such as tungsten. In FIG. 45B, the backside source/drain conductive features 82, denoted as “BVD” in the context, may land on backsides of the bottom source/drain conductive structures 14B and connect the bottom source/drain conductive structures 14B to the metal lines BML of the metallization layer BM0.

In FIG. 45C, source/drain conductive features 80, denoted as “VD” in the context, may land on one of the top source/drain conductive structures 14T and connect the one of the top source/drain conductive structures 14T to the metal lines ML of the metallization layer M0.

In FIG. 45C, cut-poly features, denoted as “CPO” in the context, may be disposed between two gate structures 12T/12B. The cut-poly features may be an isolation feature that electrically isolate one of the gate structures 12T/12B from another one of the gate structures 12T/12B. Other details regarding the configuration of the top transistors PD and PG are similar to that of the top transistors T2 illustrated previously, other details regarding the configuration of the bottom transistors PD and DMY-P are similar to that of the bottom transistors T1 illustrated previously, and thereto not repeated herein.

In the layout diagrams, side connection structures SC3, denoted as “Side connection”, may be in contact with lateral sides of the source/drain conductive structures 14B. Each of the side connection structures SC3 may electrically connect a source/drain conductive structure 14B of one of the transistors PU to a gate structure 12B of another one of the transistors PU. Other details of the present embodiments are similar those illustrated above, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a side connection structure is designed in STI regions, along the same direction as the active region in the layouts, in which the side connection structure electrically connects one of source/drain conductive structures and a gate structure of one transistor to one of source/drain conductive structures and a gate structure of another transistor. Another advantage is that power conductive features are designed in STI regions, along the same direction as the active region in the layouts, and devices can be electrically connected to or isolated from the power conductive features depending on circuit design, thereby achieving better electromagnetic interference resolution (EMIR). Still another advantage is that a vertical conductive feature is designed in CPODE, along the same direction as the gate structure in the layouts, in which the vertical conductive feature electrically connects a source/drain node of a bottom transistor to a source/drain node of a top transistor.

According to some embodiments of the present disclosure, an integrated circuit device includes a first stack structure, a second stack structure, and a side connection structure. The first stack structure includes a first transistor and a second transistor vertically stacked over the first transistor. The second stack structure includes a third transistor and a fourth transistor vertically stacked over the third transistor. Each of the first to fourth transistors includes an active layer, a gate structure, and a source/drain contact. The active layer includes a channel region and a source/drain region on a side of the channel region, in which the active layer extends substantially along a first direction in a top view. The gate structure wraps around the channel region, in which the gate structure extends substantially along a second direction orthogonal to the first direction in the top view. The source/drain contact surrounds the source/drain region. The side connection structure extends substantially along the first direction in the top view, in which the side connection structure electrically connects one of the source/drain contact and the gate structure of the first transistor of the first stack structure to one of the source/drain contact and the gate structure of the third transistor of the second stack structure.

According to some embodiments of the present disclosure, an integrated circuit device includes plural first stack structures, plural second stack structures, a top power conductive feature, and a first top isolation layer. Each of the first stack structures includes a first transistor and a second transistor vertically stacked over the first transistor. Each of the second stack structures comprising a third transistor and a fourth transistor vertically stacked over the third transistor. Each of the first to fourth transistors includes an active layer, a gate structure, and a source/drain contact. The active layer includes a channel region and a source/drain region on a side of the channel region. The active layer extends substantially along a first direction in a top view. The gate structure wraps around the channel region. The gate structure extends substantially along a second direction orthogonal to the first direction in the top view. The source/drain contact surrounds the source/drain region. The top power conductive feature is between the plurality of the first stack structures and the plurality of the second stack structures and extending substantially along the first direction in the top view. The top power conductive feature is laterally aligned with the source/drain contact of the second transistor and the source/drain contact of the fourth transistor. The first top isolation layer spaces the top power conductive feature from the source/drain contact of the second transistor of one of the first stack structures.

According to some embodiments of the present disclosure, a method for fabricating an integrated circuit device is provided. The method includes forming a bottom active layer, wherein the bottom active layer extends substantially along a first direction; forming a top active layer above the bottom active layer, wherein the bottom active layer extends substantially along the first direction; forming a gate structure wrapping around a channel region of the bottom active layer and a channel region of the top active layer, wherein the gate structure extends substantially along a second direction orthogonal to the first direction; and forming a vertical conductive feature at an end of the bottom active layer and at an end of the top active layer, wherein the vertical conductive feature extends substantially along the second direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a first stack structure comprising a first transistor and a second transistor vertically stacked over the first transistor;
a second stack structure comprising a third transistor and a fourth transistor vertically stacked over the third transistor, wherein each of the first to fourth transistors comprises:
an active layer, comprising a channel region and a source/drain region on a side of the channel region, wherein the active layer extends substantially along a first direction in a top view;
a gate structure wrapping around the channel region, wherein the gate structure extends substantially along a second direction orthogonal to the first direction in the top view; and
a source/drain contact on the source/drain region; and
a side connection structure extending substantially along the first direction in the top view, wherein the side connection structure electrically connects one of the source/drain contact and the gate structure of the first transistor of the first stack structure to one of the source/drain contact and the gate structure of the third transistor of the second stack structure.

2. The integrated circuit device of claim 1, wherein the active layer of the first transistor is aligned with the active layer of the third transistor substantially along the first direction.

3. The integrated circuit device of claim 1, wherein the side connection structure electrically connects the source/drain contact of the first transistor of the first stack structure to the source/drain contact of the third transistor of the second stack structure.

4. The integrated circuit device of claim 3, wherein the gate structure of the first transistor of the first stack structure is spaced apart from the side connection structure.

5. The integrated circuit device of claim 1, wherein the side connection structure electrically connects the gate structure of the first transistor of the first stack structure to the gate structure of the third transistor of the second stack structure.

6. The integrated circuit device of claim 1, wherein the side connection structure electrically connects the gate structure of the first transistor of the first stack structure to the source/drain contact of the third transistor of the second stack structure.

7. The integrated circuit device of claim 1, wherein a top surface of the side connection structure is below a bottom surface of the channel region of the second transistor.

8. The integrated circuit device of claim 1, wherein the side connection structure comprises a metal.

9. An integrated circuit device, comprising:
a plurality of first stack structures, each of the first stack structures comprising a first transistor and a second transistor vertically stacked over the first transistor;
a plurality of second stack structures, each of the second stack structures comprising a third transistor and a fourth transistor vertically stacked over the third transistor, wherein each of the first to fourth transistors comprises:
an active layer, comprising a channel region and a source/drain region on a side of the channel region, wherein the active layer extends substantially along a first direction in a top view;
a gate structure wrapping around the channel region, wherein the gate structure extends substantially along a second direction orthogonal to the first direction in the top view; and
a source/drain contact on the source/drain region;
a top power conductive feature between the plurality of the first stack structures and the plurality of the second stack structures and extending substantially along the first direction in the top view, wherein the top power conductive feature is laterally aligned with the source/drain contact of the second transistor and the source/drain contact of the fourth transistor; and
a first top isolation layer spacing the top power conductive feature from the source/drain contact of the second transistor of one of the first stack structures.

10. The integrated circuit device of claim 9, further comprising:
a second top isolation layer spacing the top power conductive feature from the source/drain contact of the fourth transistor of one of the second stack structures.

11. The integrated circuit device of claim 9, wherein the top power conductive feature is in contact with the source/drain contact of the fourth transistor of one of the second stack structures.

12. The integrated circuit device of claim 9, further comprising:
a bottom power conductive feature between the plurality of the first stack structures and the plurality of the second stack structures and extending substantially along the first direction in the top view, wherein the bottom power conductive feature is laterally aligned with the source/drain contact of the first transistor and the source/drain contact of the third transistor; and
a first bottom isolation layer spacing the bottom power conductive feature from the source/drain contact of the first transistor of one of the first stack structures.

13. The integrated circuit device of claim 12, further comprising:
a second bottom isolation layer spacing the bottom power conductive feature from the source/drain contact of the third transistor of one of the second stack structures.

14. The integrated circuit device of claim 9, wherein the top power conductive feature comprises a metal.

15. A method for fabricating an integrated circuit device, comprising:
forming a bottom active layer, wherein the bottom active layer extends substantially along a first direction;
forming a top active layer above the bottom active layer, wherein the bottom active layer extends substantially along the first direction;
forming a gate structure wrapping around a channel region of the bottom active layer and a channel region of the top active layer, wherein the gate structure extends substantially along a second direction orthogonal to the first direction; and
forming a vertical conductive feature at an end of the bottom active layer and at an end of the top active layer, wherein the vertical conductive feature extends substantially along the second direction.

16. The method of claim 15, further comprising:
forming a first isolation layer spacing the vertical conductive feature from the bottom active layer.

17. The method of claim 15, further comprising:
forming a second isolation layer spacing the vertical conductive feature from the top active layer.

18. The method of claim 15, further comprising:
forming a source/drain contact on a source/drain region of the bottom active layer, wherein forming the vertical conductive feature is performed such that the vertical conductive feature is in contact with one of the source/drain contact and the source/drain region of the bottom active layer.

19. The method of claim 15, further comprising:
forming a source/drain contact on a source/drain region of the top active layer, wherein forming the vertical conductive feature is performed such that the vertical conductive feature is in contact with one of the source/drain contact and the source/drain region of the top active layer.

20. The method of claim 15, further comprising:
forming a contact plug over the vertical conductive feature; and
forming a metallization layer over and in contact with the contact plug.
